(19) United States
(12) Patent Application Publication
(10) Pub. No.: US 2015/0303355 A1
(43) Pub. Date: Oct. 22, 2015

(54) SEMICONDUCTOR LIGHT EMITTING DEVICE AND METHOD FOR MANUFACTURING SAME

(71) Applicant: Kabushiki Kaisha Toshiba, Tokyo (JP)

(72) Inventor: Hideto Furuyama, Kanagawa-ken (JP)

(21) Appl. No.: 14/708,812

(22) Filed: May 11, 2015

Related U.S. Application Data
(62) Division of application No. 12/881,618, filed on Sep. 14, 2010.

(30) Foreign Application Priority Data
Apr. 26, 2010 (JP) 2010-101395

(51) Int. Cl. H01L 33/50; H01L 33/46; H01L 33/38

(52) U.S. Cl. CPC H01L 33/502; H01L 33/38; H01L 33/46

(57) ABSTRACT

According to one embodiment, a semiconductor light emitting device includes a semiconductor layer, a p-side electrode, an n-side electrode, an insulating film, a p-side draw out electrode, an n-side draw out electrode, a resin, a fluorescent layer, and a fluorescent reflecting film. The semiconductor layer includes a first face, a second face opposite to the first face, and a light emitting layer. The fluorescent layer is provided on the first face side of the semiconductor layer. The fluorescent reflecting film is provided between the first face and the fluorescent layer.

### CROSS-REFERENCE TO RELATED APPLICATION

This application is based upon and claims the benefit of priority from the prior Japanese Patent Application No.2010-101395, filed on Apr. 26, 2010; the entire contents of which are incorporated herein by reference.

### FIELD

Embodiments described herein relate generally to a semiconductor light emitting device and a method for a manufacturing the same.

### BACKGROUND

Semiconductor light emitting elements that emit light by the recombination of injected minority carriers in a pn junction of a direct bandgap semiconductor are drawing attention as next-generation illumination light sources. Generally, white light approaching sunlight is required of semiconductor light emitting elements for illumination. White semiconductor light sources include primary color (RGB) element arrays, pseudo-white light sources that mix a blue light emitting element with a yellow phosphor, primary color phosphor excitation light sources using ultraviolet light emitting elements, etc.

In such semiconductor light emitting elements, there are cases where a semiconductor substrate used for the crystal growth is peeled off.

### BRIEF DESCRIPTION OF THE DRAWINGS

FIGS. 1A to 1D are schematic views of a semiconductor light emitting device of a first embodiment;

FIG. 2 to FIG. 5 are characteristic graphs of fluorescent reflecting films;

FIG. 6A is a schematic cross-sectional view illustrating one example of the configuration of the fluorescent reflecting film, FIG. 6B is a graph illustrating the transmission spectrum and the reflectance spectrum of the fluorescent reflecting film;

FIGS. 7A to 10E illustrate a method for manufacturing the semiconductor light emitting device of the first embodiment;

FIGS. 11A to 11C are schematic cross-sectional views illustrating a method for manufacturing a first variation of the first embodiment;

FIGS. 12A to 12D are schematic cross-sectional views illustrating a method for manufacturing a second variation of the first embodiment;

FIGS. 13A to 13E are schematic cross-sectional views illustrating a method for manufacturing a semiconductor light emitting device of a second embodiment;

FIGS. 14A to 14D are schematic cross-sectional views illustrating a method for manufacturing a variation of the second embodiment;

FIGS. 15A and 15B are schematic views of a semiconductor light emitting device of a third embodiment;

FIGS. 16A to 17B are schematic views illustrating a method for manufacturing a variation of the third embodiment;

FIGS. 18A to 18B are schematic plan views illustrating one example of a pattern of the metal interconnect layer;

FIGS. 19A to 19D are schematic plan views illustrating variations of the electrode pattern;

FIGS. 20A to 20F are schematic cross-sectional views illustrating a lens formation method;

FIGS. 21A to 21C are schematic cross-sectional views illustrating another example of the lens formation method;

FIGS. 22A to 22C are schematic views of a semiconductor light emitting device having a lens of the variation;

FIGS. 23A to 23C are schematic views illustrating variations of lenses;

FIGS. 24A and 24B are schematic configuration diagrams of a semiconductor light emitting device of a first reference example;

FIG. 25A to FIG. 28B are schematic cross-sectional views of manufacturing processes of the semiconductor light emitting device of the first comparative example;

FIG. 29A to FIG. 30B are schematic plan views of manufacturing processes of the semiconductor light emitting device of the first comparative example;

FIG. 31 is a schematic cross-sectional configuration diagram of the semiconductor light emitting device of a second comparative example;

FIG. 32 is a schematic configuration cross-sectional diagram of the semiconductor light emitting device of a third comparative example; and

FIG. 33 is an enlarged view of the relevant part in FIG. 32.

### DETAILED DESCRIPTION

According to one embodiment, a semiconductor light emitting device includes a semiconductor layer, a p-side electrode, an n-side electrode, an insulating film, a p-side draw out electrode, an n-side draw out electrode, a resin, a fluorescent layer, and a fluorescent reflecting film. The semiconductor layer includes a first face, a second face opposite to the first face, and a light emitting layer. The p-side electrode and the n-side electrode are provided on the second face of the semiconductor layer. The insulating film is provided on the second face side of the semiconductor layer. The insulating film has a first opening reaching the p-side electrode and a second opening reaching the n-side electrode. The p-side draw out electrode includes a p-side metal interconnect layer and a p-side metal pillar. The p-side metal interconnect layer is provided in the first opening and on the insulating film. The p-side metal pillar is provided on the p-side metal interconnect layer. The n-side draw out electrode includes an n-side metal interconnect layer and an n-side metal pillar. The n-side metal interconnect layer is provided in the second opening and on the insulating film. The n-side metal pillar is provided on the n-side metal interconnect layer. A contact surface area between the n-side metal interconnect layer and the n-side metal pillar is greater than a contact surface area between the n-side metal interconnect layer and the n-side electrode. The resin is filled to surround the p-side metal pillar and the n-side metal pillar. The fluorescent layer is provided on the first face side of the semiconductor layer. The fluorescent reflecting film is provided between the first face and the fluorescent layer.

Embodiments will now be described with reference to the drawings. Although the descriptions herein use several specific configurations as examples, configurations having similar functions thereto are similarly practicable; and the invention is not limited to the embodiments hereinbelow. Similar components in the drawings are marked with like reference numerals.

### First Embodiment

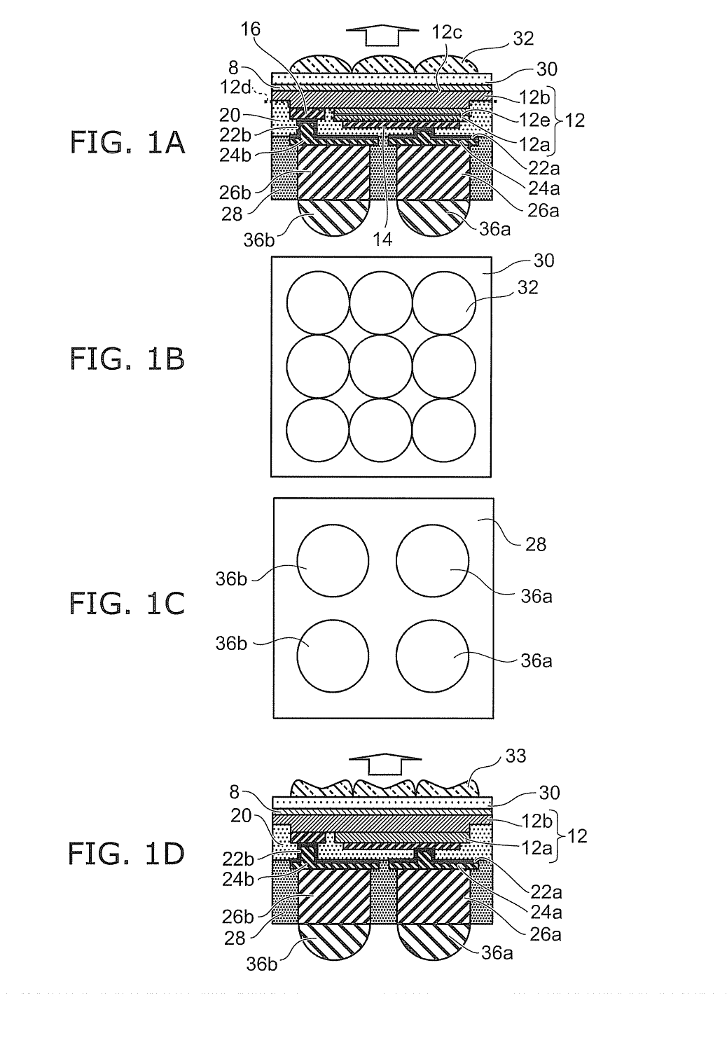

FIGS. 1A to 1D are schematic views of a semiconductor light emitting device of a first embodiment. FIG. 1A is a cross-sectional view. FIG. 1B is a top view. FIG. 1C is a bottom view. FIG. 1D is a cross-sectional view of a variation.

The manufacturing of the semiconductor light emitting device of this embodiment may proceed in the wafer state as described below. FIGS. 1A to 1D illustrate a state of being singulated from the wafer state.

The semiconductor light emitting device of this embodiment includes a semiconductor layer 12. The semiconductor layer 12 includes a first semiconductor layer 12b and a second semiconductor layer 12a. The second semiconductor layer 12a includes, for example, a p-type clad layer, a light emitting layer 12e, and an n-type clad layer. The first semiconductor layer 12b forms, for example, an n-type current path in the lateral direction.

The semiconductor layer 12 has a first face 12c and a second face 12d on a side opposite to the first face 12c. As illustrated by the broken line in FIG. 1A, the second face 12d has a difference in levels. A p-side electrode 14 is provided on the upper level portion of the different levels on the second face 12d; and an n-side electrode 16 is provided on the lower level portion on the second face 12d. The upper level portion where the p-side electrode 14 is provided, is a light emitting region having a surface area greater than the surface area of the lower level portion (a non-light emitting region) where the n-side electrode 16 is provided. The planar size of the p-side electrode 14 is greater than the planar size of the n-side electrode 16.

An insulating film 20 is provided on the second face 12d side of the semiconductor layer 12. The insulating film 20 is made of, for example, an organic material such as a resin or an inorganic material such as a silicon oxide film. A first opening is made in the insulating film 20 to reach the p-side electrode 14. A p-side seed metal 22a is provided in the first opening and on the surface of the insulating film 20. Also, a second opening is made in the insulating film 20 to reach the n-side electrode 16. An n-side seed metal 22b is provided in the second opening and on the surface of the insulating film 20.

A p-side metal interconnect layer 24a is provided in the first opening of the insulating film 20 and on the p-side seed metal 22a. A p-side metal pillar 26a is provided on the p-side metal interconnect layer 24a. An n-side metal interconnect layer 24b is provided in the second opening of the insulating film 20 and on the n-side seed metal 22b. An n-side metal pillar 26b is provided on the n-side metal interconnect layer 24b.

The p-side electrode 14 is electrically connected to the p-side metal pillar 26a via the p-side seed metal 22a and the p-side metal interconnect layer 24a. The n-side electrode 16 is electrically connected to the n-side metal pillar 26b via the n-side seed metal 22b and the n-side metal interconnect layer 24b.

The p-side seed metal 22a, the p-side metal interconnect layer 24a, and the p-side metal pillar 26a form a p-side draw out electrode. The n-side seed metal 22b, the n-side metal interconnect layer 24b, and the n-side metal pillar 26b form an n-side draw out electrode. A current is supplied to the semiconductor layer 12 via the p-side draw out electrode and the n-side draw out electrode, and the light emitting layer 12e emits light.

The contact surface area between the n-side metal interconnect layer 24b and the n-side metal pillar 26b is greater than the contact surface area between the n-side metal interconnect layer 24b and the n-side electrode 16. The contact surface area between the p-side metal interconnect layer 24a and the p-side metal pillar 26a is greater than the contact surface area between the p-side metal interconnect layer 24a and the p-side electrode 14.

In other words, the surface area of the n-side metal interconnect layer 24b connecting the n-side electrode 16 provided in a portion of the semiconductor layer 12 not including the light emitting layer 12e is greater at a face on a side opposite to the n-side electrode 16 than at a face on the n-side electrode 16 side. A portion of the n-side metal interconnect layer 24b extends to a position overlaying a position below the light emitting layer 12e.

Thereby, a wider draw out electrode can be formed from the n-side electrode 16 provided in a portion of the semiconductor layer 12 not including the light emitting layer 12e and having a small surface area via the n-side metal interconnect layer 24b while maintaining a high light output by a wider light emitting layer 12e.

The insulating film 20 is filled between the p-side seed metal 22a and the second face 12d of the semiconductor layer 12 and between the n-side seed metal 22b and the second face 12d of the semiconductor layer 12. A resin 28 is filled around the p-side metal pillar 26a and around the n-side metal pillar 26b. The resin 28 covers the surface of the insulating film 20 and is filled also between the p-side metal interconnect layer 24a and the n-side metal interconnect layer 24b.

The end face of the p-side metal pillar 26a on the side opposite to the p-side metal interconnect layer 24a and the end face of the n-side metal pillar 26b on the side opposite to the n-side metal interconnect layer 24b are exposed from the resin 28; and external terminals 36a and 36b are provided in a Ball Grid Array (BGA) configuration on the end faces, respectively. The external terminals 36a and 36b are, for example, solder balls, metal bumps, etc. The semiconductor light emitting device is mountable on a mounting substrate and the like, via the external terminals 36a and 36b.

The materials of the metal interconnect layers 24a and 24b and the metal pillars 26a and 26b may include copper, gold, nickel, silver, etc. Of these materials, it is favorable to use copper which has good thermal conductivity, high migration resistance, and excellent adhesion with insulating films. Of course, the materials are not limited to copper.

The thickness of each of the p-side metal pillar 26a, the n-side metal pillar 26b, and the resin 28 is thicker than the thickness of a stacked body including the semiconductor layer 12, the p-side electrode 14, the n-side electrode 16, the insulating film 20, the p-side seed metal 22a, the n-side seed metal 22b, the p-side metal interconnect layer 24a, and the n-side metal interconnect layer 24b.

Even in the case where the semiconductor layer 12 is thin, it is possible to maintain the mechanical strength by increasing the thickness of the p-side metal pillar 26a, the n-side metal pillar 26b, and the resin 28. The p-side metal pillar 26a and the n-side metal pillar 26b reduce the stress applied to the semiconductor layer 12 via the external terminals 36a and 36b.

A fluorescent reflecting film 8 is provided on the first face 12c of the semiconductor layer 12. A fluorescent layer 30 is provided on the fluorescent reflecting film 8 with a substantially uniform thickness. The fluorescent layer 30 has a structure in which phosphor particles are mixed, for example, in a silicone resin or glass.

The phosphor included in the fluorescent layer 30 is capable of absorbing the light (the excitation light) emitted by the light emitting layer 12e and emitting a wavelength-converted light. Accordingly, a mixed light of the light emitted by the light emitting layer 12e and the wavelength-converted light can be emitted. In the case where the light emitting layer 12e is, for example, a nitride, the blue light emitted by the light emitting layer 12e can be mixed with, for example, a yellow wavelength-converted light from a yellow phosphor to obtain a mixed color of white, lamp, etc.

In this embodiment, the fluorescent layer 30 is provided with a substantially uniform thickness proximally to the light emitting layer 12e; and the emitted light is incident on the fluorescent layer 30 prior to divergence. Therefore, it is easy to reduce uneven colors by reducing the spread between the light emitted by the light emitting layer 12e and the wavelength-converted light. The fluorescent reflecting film 8 is provided between the fluorescent layer 30 and the first face 12c of the semiconductor layer 12. The fluorescent reflecting film 8 has a relatively low reflection with respect to the light emission wavelength of the light emitting layer 12e and a relatively high reflection with respect to the light emission wavelength of the phosphor. In other words, the reflectance of the fluorescent reflecting film 8 with respect to the light emission wavelength of the phosphor is higher than the reflectance of the fluorescent reflecting film 8 with respect to the light emission wavelength of the light emitting layer 12e.

Mainly, the light from the light emitting layer 12e is emitted upward from the first face 12c of the semiconductor layer 12 as illustrated by the block arrow in FIG. 1A via the fluorescent reflecting film 8 and the fluorescent layer 30. The fluorescent reflecting film 8 has the functions of effectively irradiating the light (having a wavelength λ₀) emitted by the light emitting layer 12e onto the phosphor and reflecting the light emitted by the phosphor. In other words, although light of the wavelength λ₀ is easily transmitted, light of other wavelengths is relatively reflected.

As a result, although the excitation light Po) of the light emitting layer 12e is irradiated through the fluorescent reflecting film 8 onto the phosphor (fluorescent material), the component of the light emitted by the phosphor toward the semiconductor layer 12 (an LED chip) side is reflected by the fluorescent reflecting film 8 and output externally. In other words, the proportion of the desired light emitted by the phosphor that is lost due to internal scattering and internal absorption is reduced; and the luminous efficacy as viewed from the outside can be increased.

Specifically,

n₂h₂=λ₀(1+2m)/4(m=0, 1, 2, 3, . . . )

when 1<n₂<n₃, and

n₂h₂=λ₀(1+m)/2(m=0, 1, 2, 3, . . . )

when n₂>n₃, where the refractive index of the first semiconductor layer 12b is n₁ (about 1), the refractive index of the fluorescent reflecting film 8 is n₂, the thickness of the fluorescent reflecting film 8 is h₂, the refractive index of the fluorescent layer 30 is n₃, and each of the thickness of the first semiconductor layer 12b (h₁) and the thickness of the fluorescent layer 30 (h₃) is set sufficiently greater than λ₀.

For example, the thickness h₂ is set such that n₂h₂=λ₀/4, 3λ₀/4, 5λ₀/4, . . . , when 1<n₂<n₃ and n₂h₂=λ₀/2, λ₀, 3λ₀/2, . . . , when n₂>n₃.

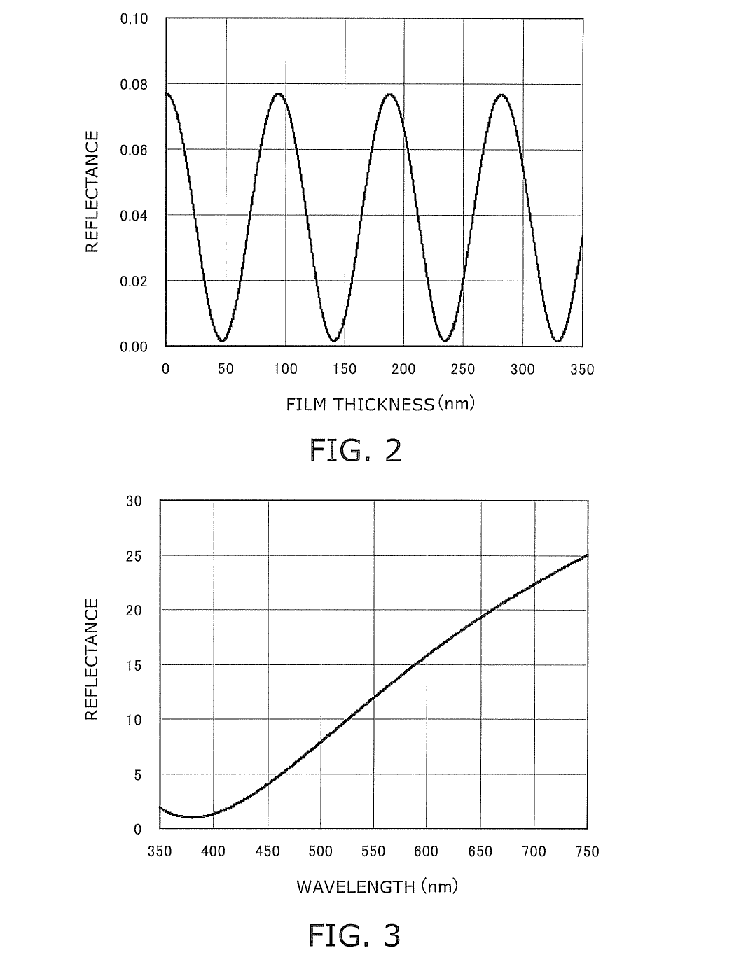

FIG. 2 illustrates the dependency of the reflectance on the film thickness (h₂) in the case where a resin sheet (n₃ being about 1.46) in which a phosphor is dispersed in a resin, for example, is used as the fluorescent layer 30 and silicon nitride (Si₃N₄ with n₂ being about 2.02), for example, is used as the fluorescent reflecting film 8.

FIG. 2 illustrates the case where the wavelength (λ₀) is 380 nm. The reflectance has minimums at film thicknesses (h₂) of the fluorescent reflecting film 8 of 47 nm, 94 nm, and 141 nm. Multiplying h₂ by n₂ gives 95 nm, 190 nm, and 285 nm and shows that these minimums correspond to thicknesses such that n₂h₂=λ₀/4, λ₀/2, and 3λ₀/4.

FIG. 3 illustrates the dependency of the reflectance on the wavelength for a film thickness h₂ at which the reflectance recited above decreases.

FIG. 3 illustrates the dependency of the reflectance on the wavelength in the case where h₂=47 nm (n₂h₂=λ₀/4). The reflectance is illustrated as a relative reflectance in the case where the reflectance (about 0.16%) of the excitation light (λ₀=380 nm) is set to 1.

It is shown that the wavelengths other than that of the excitation light have reflectances not less than the reflectance with respect to the excitation light, and that the light emitted by the phosphor can be reflected to the outside more efficiently than the case where the fluorescent reflecting film 8 is not used. For wavelengths of the so-called standard three primary colors (Red: 700 nm, Green: 546 nm, and Blue: 436 nm), reflectances of about 22 times (R), about 12 times (G), and about 3 times (B) the reflectance of the excitation light are obtained, that is, red (R) being 3.6%, green (G) being 1.9%, and blue (B) being 0.5%, respectively. FIG. 3 corresponds to the case where a combination of ultraviolet excitation and phosphors of the three colors of RGB in a phosphor sheet is used and the like.

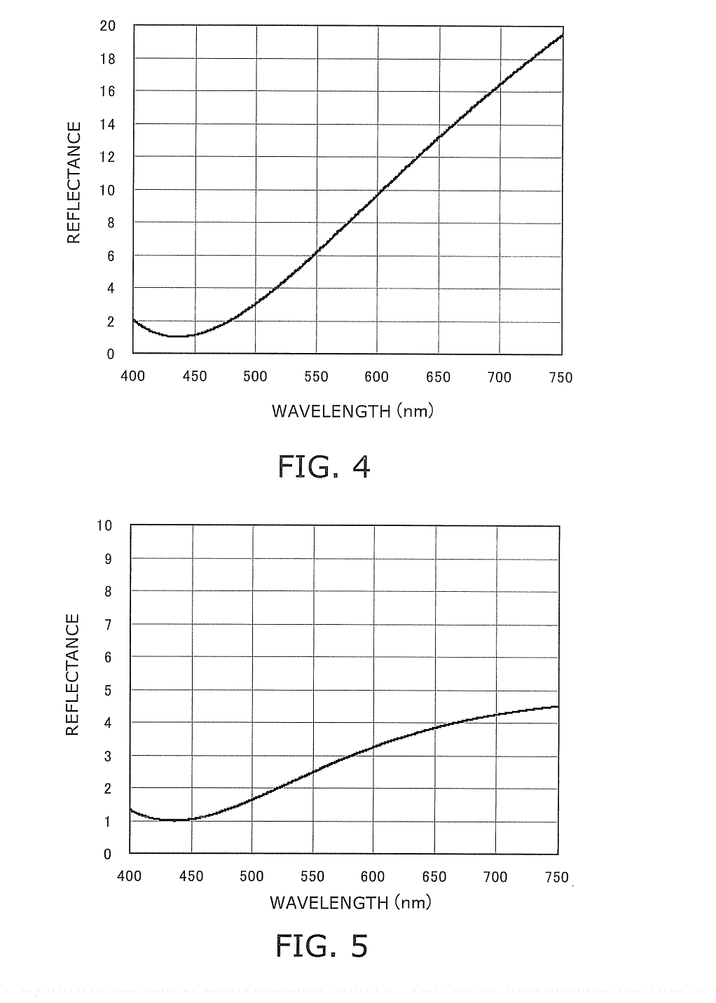

FIG. 4 illustrates the dependency of the reflectance on the wavelength in the case where the excitation light is blue light (λ₀=436 nm) and h₂=54 nm (n₂h₂=λ₀/4).

Although the reflectance of the excitation light is similarly about 0.16%, reflectances of about 16 times (R) and about 6 times (G) the reflectance of the excitation light are obtained, that is, R being 2.6% and G being 0.9%, respectively. FIG. 4 corresponds to the case where a combination of blue light excitation and phosphors of the two colors of RG in a phosphor sheet is used and the like.

FIG. 5 illustrates the dependency of the reflectance on the wavelength in the case where the excitation light is blue light (λ₀=436 nm), silicon oxide (SiO₂ with n₂ being about 1.46), for example, is used as the fluorescent reflecting film 8, and h₂=150 nm (n₂h₂=λ₀/2).

This example corresponds to the case where the phosphor is formed by directly forming a yellow phosphor (e.g., YAG (Ce)) on SiO₂ by laser sintering and the like. Although the reflectance of the excitation light (λ₀=436 nm) is similarly about 3.0%, the reflectance at the maximum fluorescent wavelength (550 nm) of the YAG (Ce) phosphor is 7.4%, i.e., a reflectance of about 2.5 times. This example is effective as a pseudo-white light source in applications requiring brightness.

Although the examples recited above illustrate dependencies of the fluorescent reflecting film 8 on the wavelength, it goes without saying that the description recited above is but one example; and optimization should be performed when combining the excitation wavelength, the dependency on the wavelength of the fluorescent efficiency of the phosphor to be used, etc.

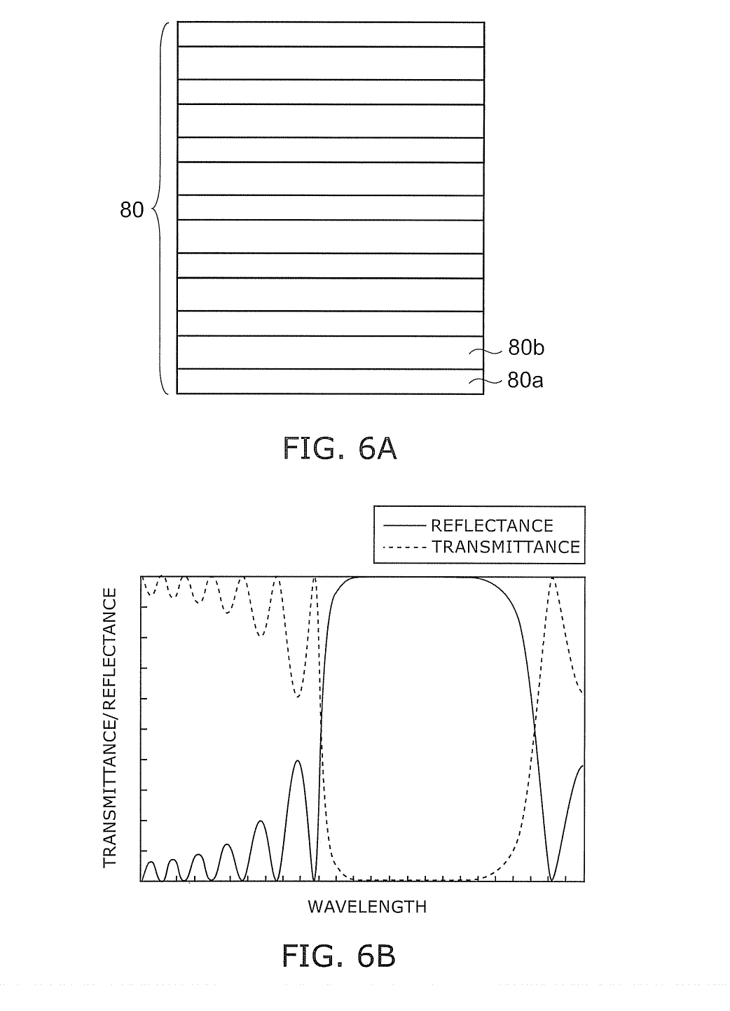

As illustrated in FIG. 6A, a fluorescent reflecting film 80 may have a multilayered structure. Such a fluorescent reflecting film 80 has a structure in which a first dielectric film 80a is repeatedly stacked alternately with a second dielectric film 80b, where the first dielectric film 80a and the second dielectric film 80b have mutually different refractive indexes and film thicknesses.

FIG. 6B is a graph illustrating the transmission spectrum and the reflectance spectrum of the fluorescent reflecting film 80. This graph shows that the intensity of the transmittance and the intensity of the reflectance are inverted in a certain wavelength region. In other words, in a certain wavelength region, substantially none of the light is transmitted and a high ability to reflect light is obtained. By stacking the dielectric film into multiple layers, a fluorescent reflecting film having the desired reflective characteristics can be easily realized.

In this embodiment as described below, the components are formed at the wafer level. Therefore, the size of the semiconductor light emitting device can approach the size of the bare chip (the semiconductor layer 12); and downsizing is easy. Also, it is possible to omit the sealing resin; and thickness reductions are easy.

By further providing a convex lens 32 made of, for example, quartz glass, etc., on the fluorescent layer 30 as illustrated in FIGS. 1A and 1B, the luminance can be increased easily by concentrating mixed light such as white light or lamp light by the convex lens 32. Further, the convex lens 32 can be provided proximally to the light emitting layer 12e without interposing a sealing resin. Therefore, the size of the lens can be reduced; and downsizing is easy. Moreover, the convex lens 32 can be formed in the wafer state. Therefore, assembly processes having high productivity are possible; and cost reductions are easy.

In the variation illustrated in FIG. 1D, the emitted light may be diverged by providing a concave lens 33 instead of the convex lens. For example, when used in a backlight light source, etc., it is necessary for the emitted light to be incident on a light guide plate from a side face such that the emitted light spreads along the surface of the light guide plate. In such a case, it is suitable to use the concave lens 33.

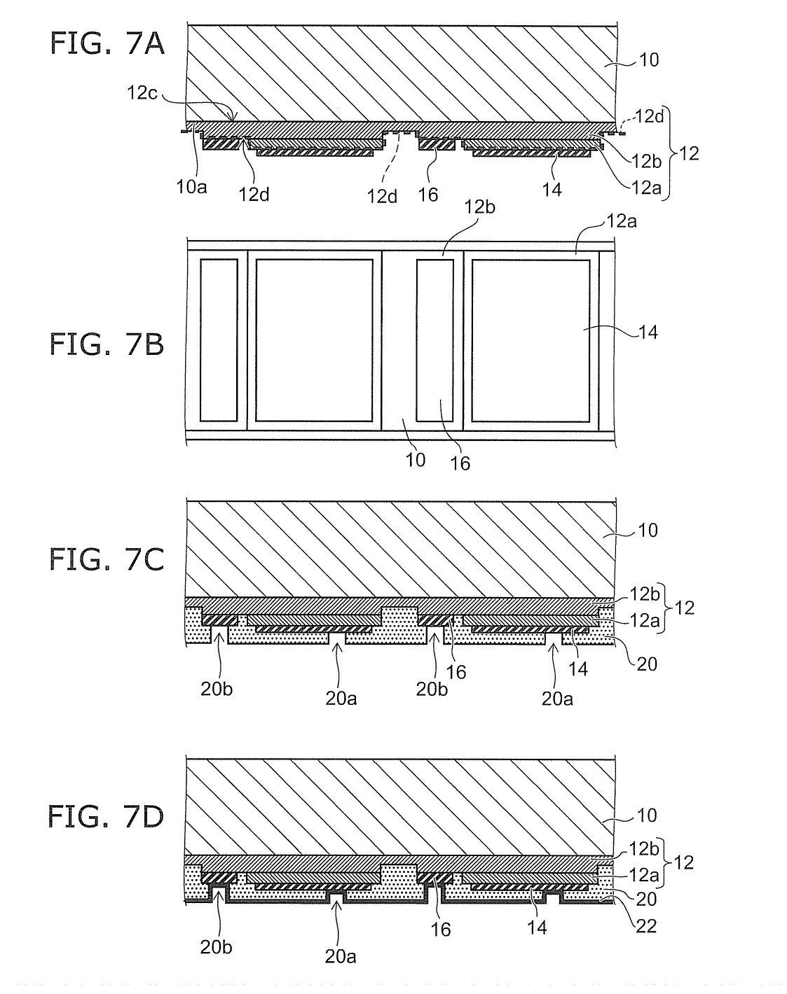

A method for manufacturing the semiconductor light emitting device of the first embodiment will now be described with reference to FIG. 7A to FIG. 10E.

FIGS. 7A to 7D illustrate the semiconductor layer 12 formation process to the seed metal formation process.

First, as illustrated in FIG. 7A, the semiconductor layer 12 is formed on a first face 10a of a substrate 10 made of, for example, sapphire and the like. The semiconductor layer 12 includes the first semiconductor layer 12b, which includes a buffer layer and an n-type layer, and the second semiconductor layer 12a, which includes a light emitting layer.

The first face 12c of the semiconductor layer 12 is adjacent to the first face 10a of the substrate 10 and is substantially flat. The second face 12d (the broken line) of the semiconductor layer 12 has a difference in levels including the surface of the second semiconductor layer 12a and the surface of the first semiconductor layer 12b. The surface of the first semiconductor layer 12b is exposed by removing the second semiconductor layer 12a.

Then, the p-side electrode 14 is formed on the surface of the second semiconductor layer 12a; and the n-side electrode 16 is formed on the surface of the first semiconductor layer 12b on the level lower than the second semiconductor layer 12a (the first face 12c side). FIG. 7B illustrates an example pattern of the p-side electrode 14 and the n-side electrode 16.

As illustrated in FIG. 7C, the insulating film 20 is formed to cover the p-side electrode 14 and the n-side electrode 16. A first opening 20a is made in the insulating film 20 to reach the p-side electrode 14; and a second opening 20b is made in the insulating film 20 to reach the n-side electrode 16.

Then, as illustrated in FIG. 7D, a seed metal 22 made of, for example, Ti/Cu, etc., is formed by sputtering in the openings 20a and 20b and on the surface of the insulating film 20.

For example, the n-side electrode 16 may have a stacked structure of Ti/Al/Pt/Au; and the p-side electrode 14 may have a stacked structure of Ni/AI (or Ag)/Au, etc. In the case where the p-side electrode 14 includes a highly reflective film such as Al or Ag, it is easy to reflect the light emitted by the light emitting layer 12e upward to extract a high light output. Moreover, because the seed metal 22 is provided, a pad made of Au can be omitted.

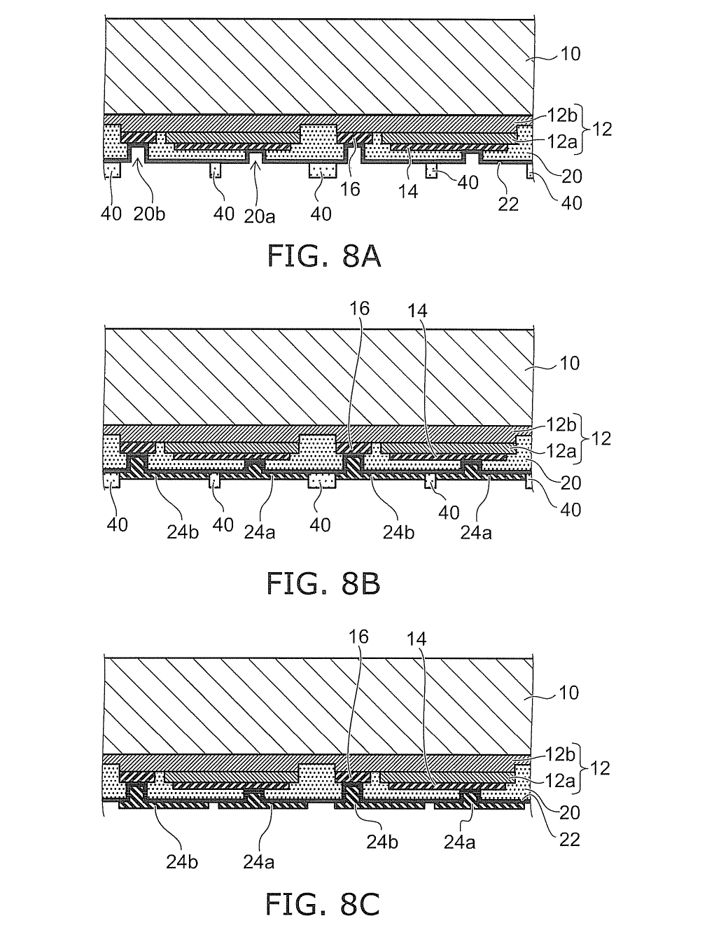

FIGS. 8A to 8C illustrate the metal interconnect layer formation process.

A photoresist 40, for example, is patterned on the seed metal 22 (FIG. 8A). The metal (e.g., copper) interconnect layer 24 is selectively formed by electroplating by using the patterned photoresist 40 as a mask (FIG. 8B). Thereby, the p-side metal interconnect layer 24a and the n-side metal interconnect layer 24b are formed in separation from each other. The p-side metal interconnect layer 24a and the n-side metal interconnect layer 24b are formed simultaneously by plating using the seed metal 22 as a current path.

At this time, the metal interconnect layers 24a and 24b are formed such that the bottom surface areas of the metal interconnect layers 24a and 24b are greater than the bottom surface areas or the sizes of the openings 20a and 20b made in the insulating film 20. In such a case, the thin seed metal 22 forms the current path for the electroplating process. Subsequently, the photoresist 40 is removed using ashing or the like to form the structure illustrated in FIG. 8C.

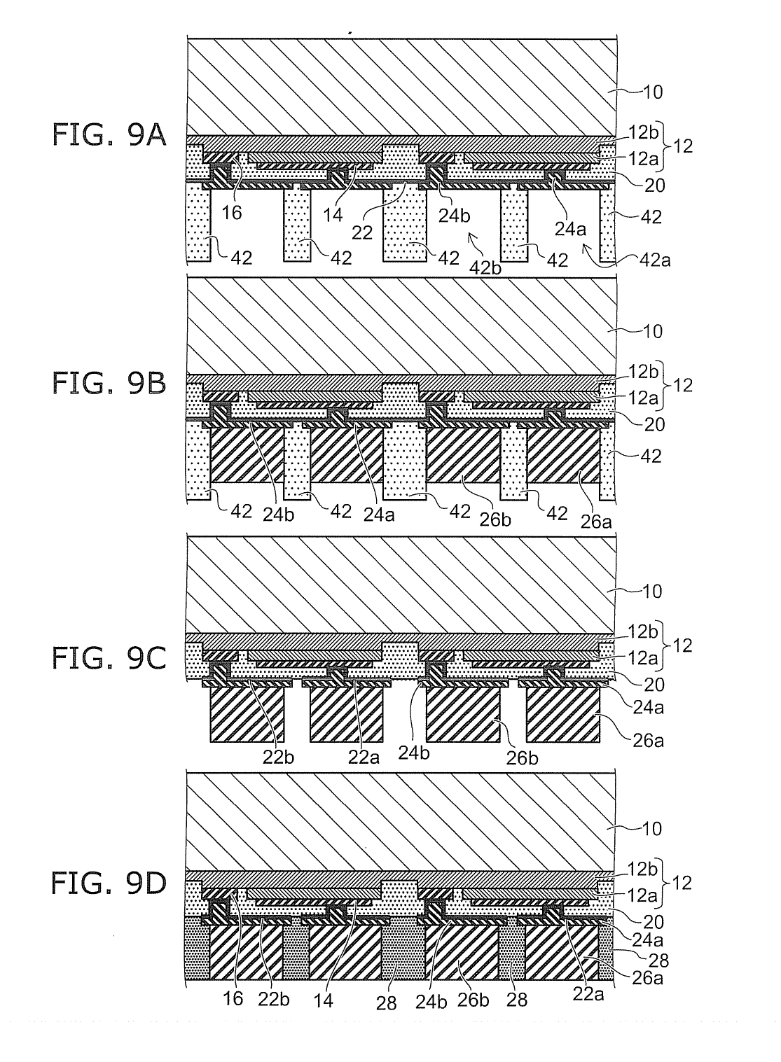

FIGS. 9A to 9D illustrate the metal pillar formation process and the reinforcing resin formation process.

As illustrated in FIG. 9A, a thick film photoresist 42 is patterned to make an opening 42a on the p-side metal interconnect layer 24a and an opening 42b on the n-side metal interconnect layer 24b. The p-side metal pillar 26a is formed in the opening 42a and the n-side metal pillar 26b is formed in the opening 42b using electroplating (FIG. 9B). In such a case as well, the thin seed metal 22 forms a current path of the electroplating process; and the p-side metal pillar 26a and the n-side metal pillar 26b are formed simultaneously.

By setting the thickness of the metal pillars 26a and 26b to be in a range of, for example, 10 to several hundred μm, the strength of the semiconductor light emitting device can be maintained even when the substrate 10 is separated.

Subsequently, the resist 42 is removed using ashing or the like; and the exposed regions of the seed metal 22 are removed by, for example, wet etching. Thereby, the seed metal 22 exposed between the p-side metal interconnect layer 24a and the n-side metal interconnect layer 24b is removed;

and the p-side seed metal 22a and the n-side seed metal 22b are separated as illustrated in FIG. 9C.

As illustrated in FIG. 9D, the resin 28 is formed around the metal pillars 26a and 26b such that the thickness of the resin 28 is substantially the same or less than the thickness of the metal pillars 26a and 26b. Subsequently, the substrate 10 is removed. By removing the substrate 10, a thinner semiconductor light emitting device can be provided.

Here, the layer made of the resin and the metal which forms the support body of the semiconductor layer 12 after removing the substrate 10 is flexible; and the metal is plated at substantially room temperature. Therefore, relatively little residual stress occurs with the substrate 10. Thus, the substrate 10 is separated in a state in which the semiconductor layer 12 is fixed to a support body which has little residual stress and is flexible. Therefore, discrepancies such as cracks in the semiconductor layer 12 do not occur; and manufacturing with high yields is possible.

That is, the layer made of the resin and the metal is flexible, and the metal is formed by plating at near room temperature. Hence, the residual stress occurring with respect to the translucent substrate 10 is relatively low.

In the conventional technique for separating the semiconductor layer from the translucent substrate at wafer level, for example, it is bonded to a silicon substrate with a metal layer formed thereon using Au-Sn solder at a high temperature of 300° C. or more, and then the semiconductor layer made of GaN is separated by laser irradiation. However, in this conventional technique, the translucent substrate and the silicon substrate being different in thermal expansion coefficient are both rigid, and are bonded together at high temperature.

Hence, a high residual stress remains between these substrates. Consequently, when the separation is started by laser irradiation, the residual stress is locally relieved from the separated portion and unfortunately causes cracks in the thin, brittle semiconductor layer.

In contrast, in this embodiment, the residual stress is low, and the semiconductor layer 12 is separated in the state of being fixed to a flexible support. Hence, the device can be manufactured at high yield without trouble such as cracking in the semiconductor layer 12.

Although, for example, the normal chip size is several hundred μm to several mm in the case where the semiconductor layer 12 is a nitride material, in this example, it is easy to obtain a downsized semiconductor light emitting device having a size approaching such a chip size.

By using such a manufacturing method, it is unnecessary to use a mounting member such as a leadframe or ceramic substrate; and it is possible to perform the interconnect processes and the sealing processes at the wafer level. It is also possible to perform inspections at the wafer level. Therefore, the productivity of the manufacturing processes can be increased; and as a result, cost reductions are easy.

FIG. 10A illustrates the state after removing the substrate 10.

After removing the substrate 10, the fluorescent reflecting film 8 is formed on the first face 12c of the semiconductor layer 12 as illustrated in FIG. 10B. The fluorescent reflecting film 8 is formed by, for example, Chemical Vapor Deposition (CVD) or sputtering at a temperature at which the resin 28 (and, in the case where a resin is used as the insulating film 20, that resin as well) does not melt. For example, in the case where plasma CVD is used at 250° C., a SiO₂ film or a Si₃N₄ film may be deposited on the first face 12c as the fluorescent reflecting film 8. In the case where sputtering is used, it is desirable to cool the susceptor which supports the wafer.

As illustrated in FIG. 6A, the fluorescent reflecting film 80 may be formed on the first face 12c by repeatedly stacking the first dielectric film 80a alternately with the second dielectric film 80b.

After forming the fluorescent reflecting film 8, the fluorescent layer 30 is formed thereupon. For example, phosphor paste, in which a phosphor is dispersed in a resin matrix, is formed on the fluorescent reflecting film 8 by screen printing and then cured by heat treatment. Also, the resin matrix may be an ultraviolet-curing resin; and the curing may be performed by Ultra-Violet (UV) light. In such a case, the phosphor may include, for example, the three mixed colors of RGB; or separate pastes may be overlaid.

As illustrated in FIG. 10C, the convex lens 32 is formed on the fluorescent layer 30 using quartz glass or the like. As illustrated in FIG. 10D, the external terminals 36a and 36b are formed on the end faces of the metal pillars 26a and 26b.

Then, as illustrated in FIG. 10E, singulation is performed by dicing. The singulation is easy because the rigid substrate 10 has already been removed. Methods for cutting may include mechanical cutting using a diamond blade, etc., cutting by laser irradiation, cutting by high pressure water, etc.

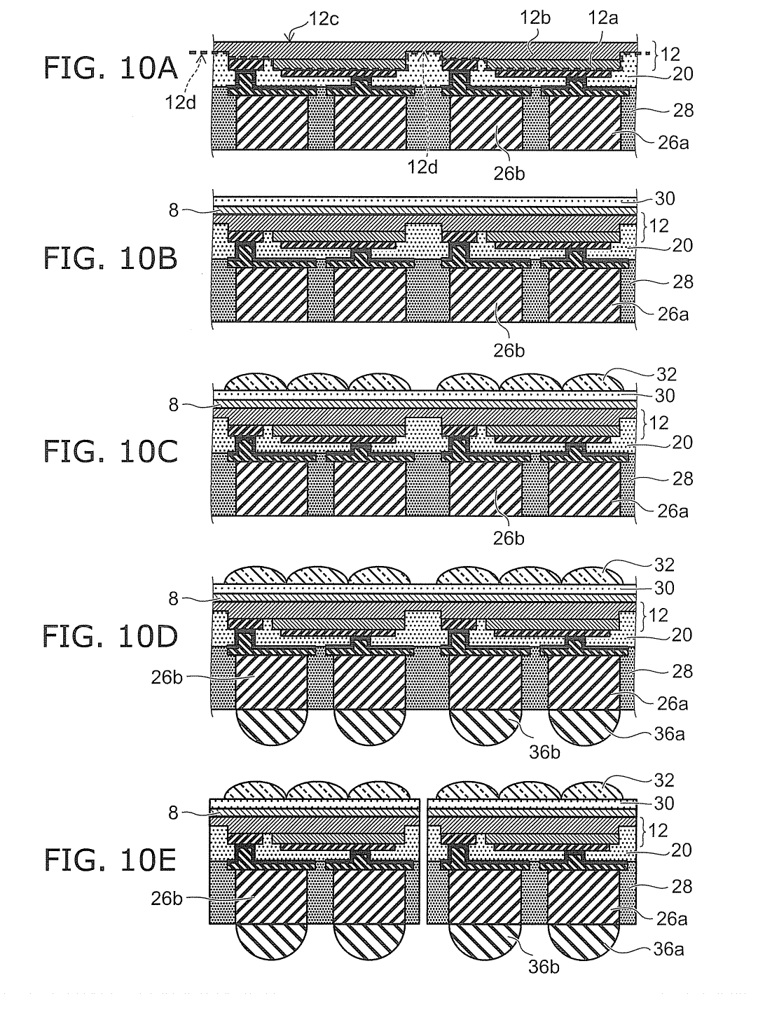

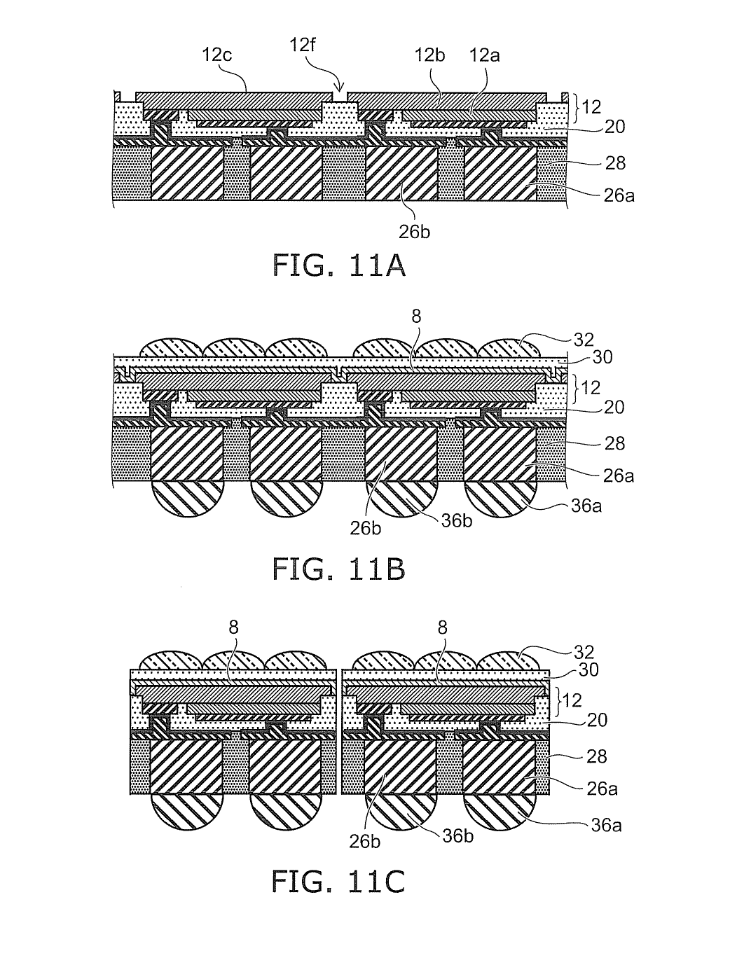

In the processes described above, the first semiconductor layer 12b is continuous along the first face 10a of the substrate 10. This is because forming the semiconductor layer 12 over the entire surface of the wafer makes it easier to separate the semiconductor layer 12, which is made of GaN, from the substrate 10 by laser irradiation. In such a case, it is desirable to fix the wafer including the semiconductor layer 12 by vacuum-attachment, adhesion, etc., on a flat tool or jig. FIGS. 11A to 11C are cross-sectional views of processes, illustrating a method for manufacturing a first variation of the first embodiment.

In this variation, after the substrate 10 is separated, a trench 12f is made in the first semiconductor layer 12b as illustrated in FIG. 11A by, for example, re-irradiating the wafer including the semiconductor layer 12 in the fixed state with a laser. The trench 12f separates the semiconductor layer 12 into a plurality. Alternatively, the semiconductor layer 12 may be separated by making the trench 12f by a combination of photolithography and etching.

Subsequently, as illustrated in FIG. 11B, the fluorescent reflecting film 8 is formed on the first face 12c and in the trench 12f. Then, the fluorescent layer 30 and the convex lens 32 are formed thereupon. Then, the external terminals 36a and 36b are formed; and singulating is performed as illustrated in FIG. 11C.

The rigid and thin semiconductor layer 12 is separated into a small size by the trench 12f. Therefore, the risk of the semiconductor layer 12 breaking during subsequent handling of the wafer is reduced.

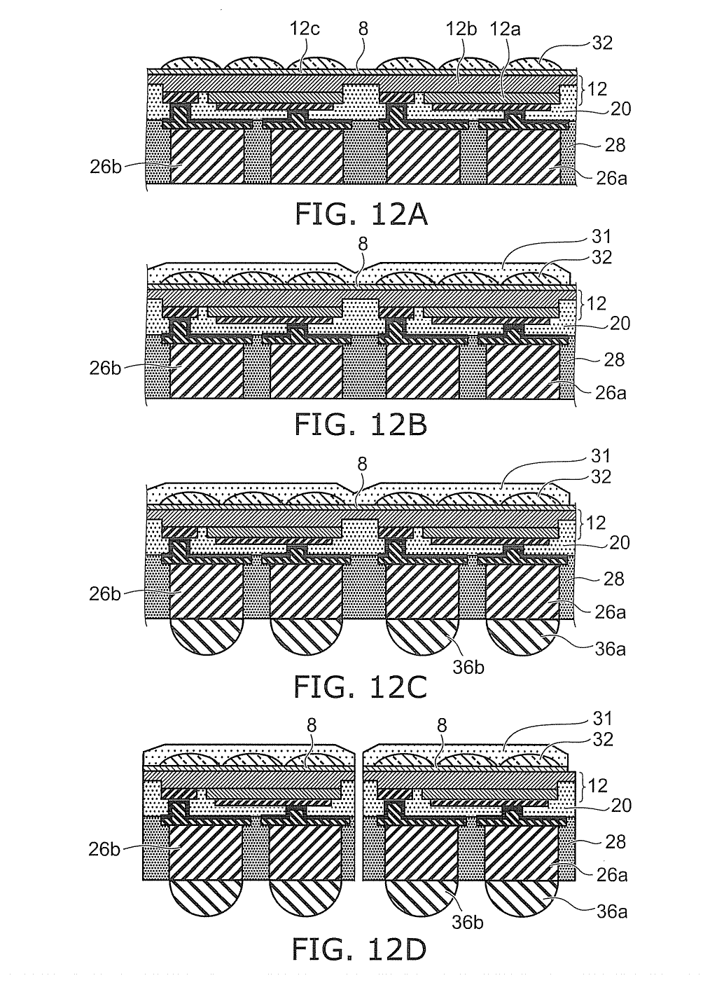

FIGS. 12A to 12D are cross-sectional views of processes, illustrating a method for manufacturing a second variation of the first embodiment.

In this variation as illustrated in FIG. 12A, the fluorescent reflecting film 8 is formed on the first face 12c of the semiconductor layer 12. Subsequently, the convex lens 32 is formed thereupon. Subsequently, as illustrated in FIG. 12B, a fluorescent layer 31 is formed on the convex lens 32. Then, the external terminals 36a and 36b are formed as illustrated in FIG. 12C; and the singulation is performed as illustrated in FIG. 12D.

### Second Embodiment

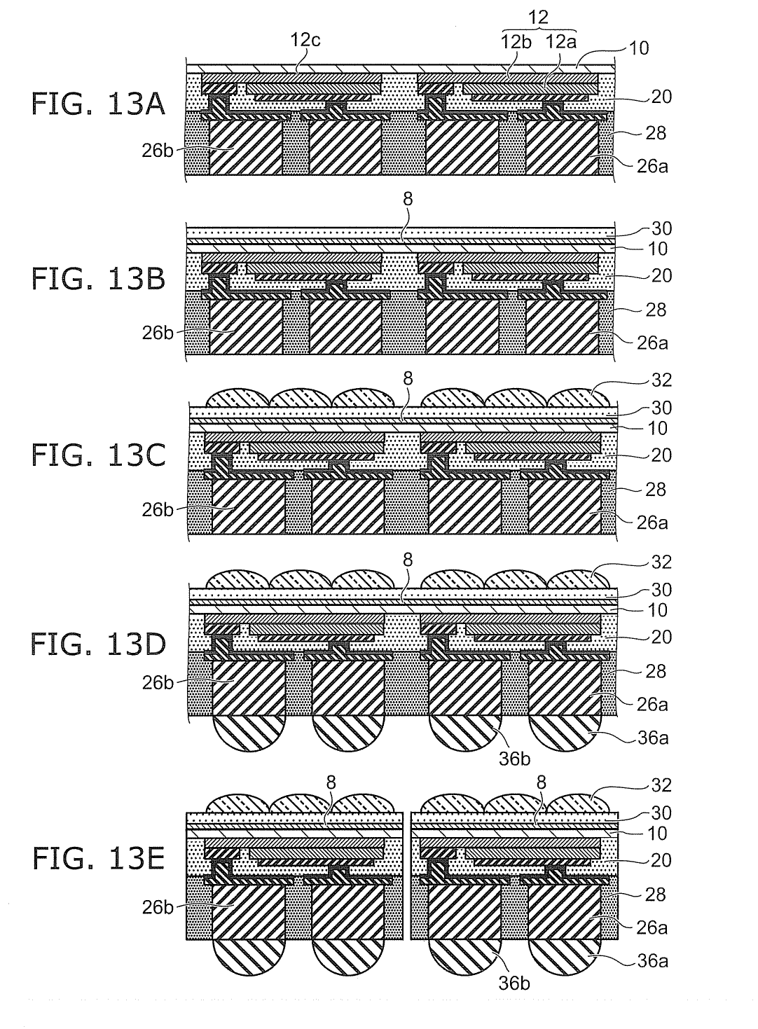

FIGS. 13A to 13E are cross-sectional views of processes, illustrating a method for manufacturing a semiconductor light emitting device of a second embodiment.

In this embodiment, the substrate 10 thinly remains on the first face 12c. Leaving about several tens of micrometers, for example, of the substrate 10 makes it easier to provide more mechanical strength than the structure in which all of the substrate 10 is removed.

The fluorescent reflecting film 8 is formed on the thinly-remaining substrate 10 as illustrated in FIG. 13B; and the fluorescent layer 30 is formed thereupon. The convex lens 32 is formed on the fluorescent layer 30 (FIG. 13C). Then, the external terminals 36a and 36b are formed (FIG. 13D); and the singulation is performed (FIG. 13E).

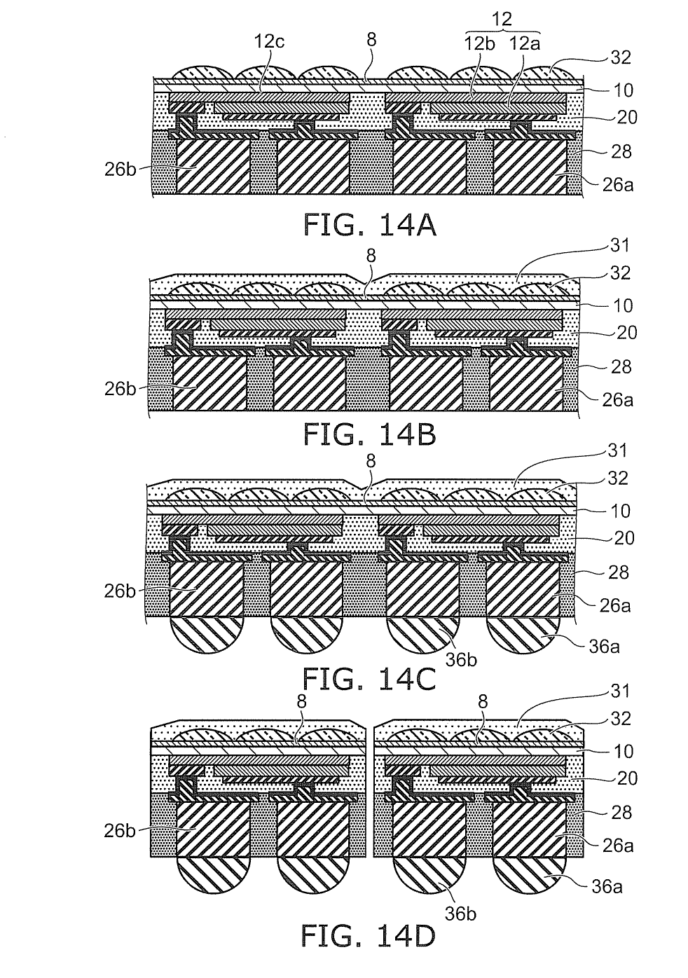

FIGS. 14A to 14D are cross-sectional views of processes, illustrating a method for manufacturing a variation of the second embodiment.

As illustrated in FIG. 14A, the fluorescent reflecting film 8 is formed on the substrate 10. Subsequently, the convex lens 32 is formed on the fluorescent reflecting film 8. Subsequently, the fluorescent layer 31 is formed on the convex lens 32 (FIG. 14B). Then, the external terminals 36a and 36b are formed (FIG. 14C); and the singulation is performed (FIG. 14D).

### Third Embodiment

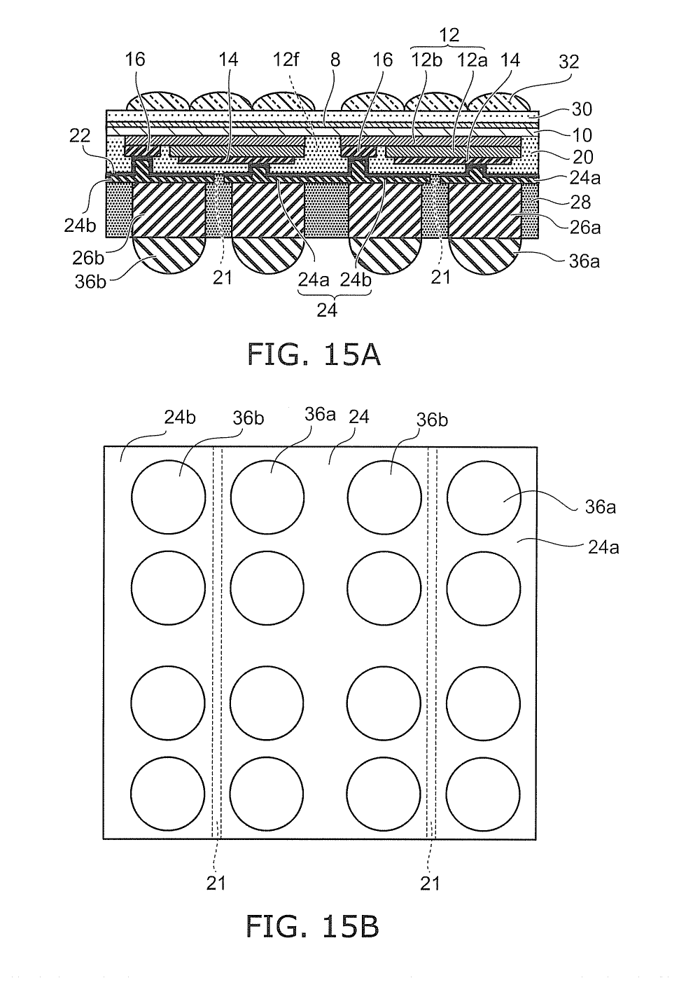

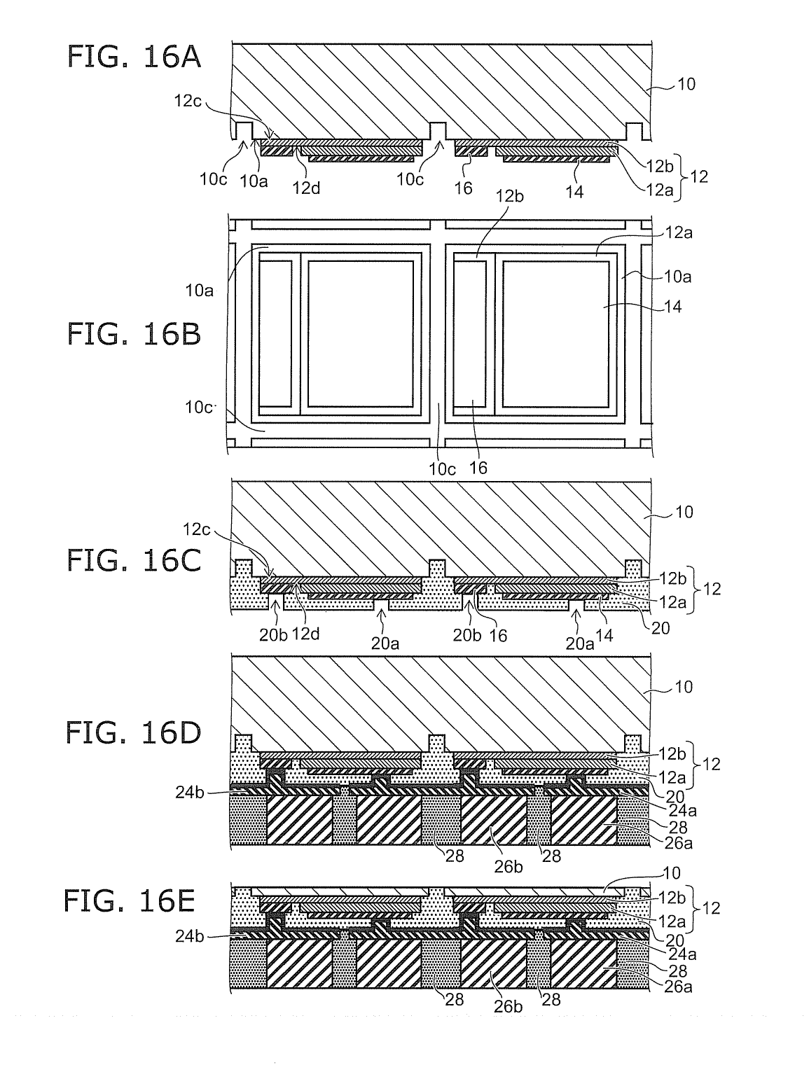

FIG. 15A is a cross-sectional view of a semiconductor light emitting device of a third embodiment. FIG. 15B is a bottom view.

This embodiment includes multiple semiconductor layers 12 separated by the trench 12f. For adjacent stacked bodies, the p-side metal interconnect layer 24a of one of the stacked bodies (the first stacked body) is patterned to be linked to the n-side metal interconnect layer 24b of one other stacked body (the second stacked body) to form the metal interconnect layer 24. It is unnecessary the remove the seed metal 22 between the first stacked body and the second stacked body.

In the first stacked body, the p-side metal interconnect layer 24a and the n-side metal interconnect layer 24b are separated by a trench 21. Similarly, in the second stacked body, the p-side metal interconnect layer 24a and the n-side metal interconnect layer 24b are separated by the trench 21.

Thus, the seed metal 22 and the metal interconnect layer 24 are linked between adjacent stacked bodies (light emitting elements). In other words, it is possible to connect two light emitting elements in series. Thus, by connecting in series, it is easy to increase the optical output.

Of course, the number of light emitting elements connected in series is not limited to two; and many more may be connected in series. It is also possible to mutually link and connect adjacent stacked bodies in parallel in a direction intersecting the direction in which the first and second stacked bodies are arranged.

Although FIG. 15B illustrates the seed metal 22 and the metal interconnect layer 24 being linked among two-by-two light emitting elements, it is not always necessary for the two-by-two light emitting elements to be separated on the outside. If such a configuration is continuous over the entire surface of the wafer, any unit of light emitting elements can be cut out.

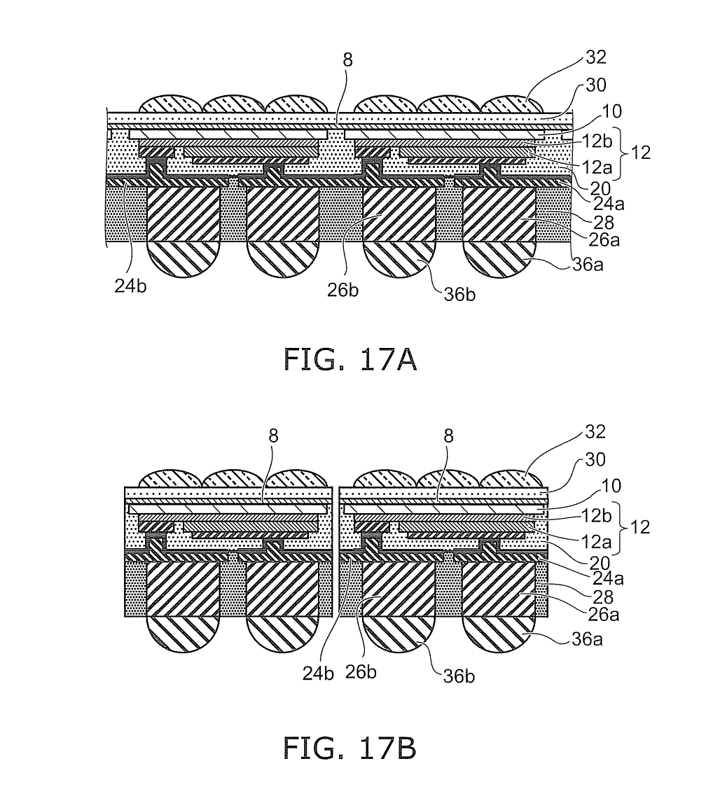

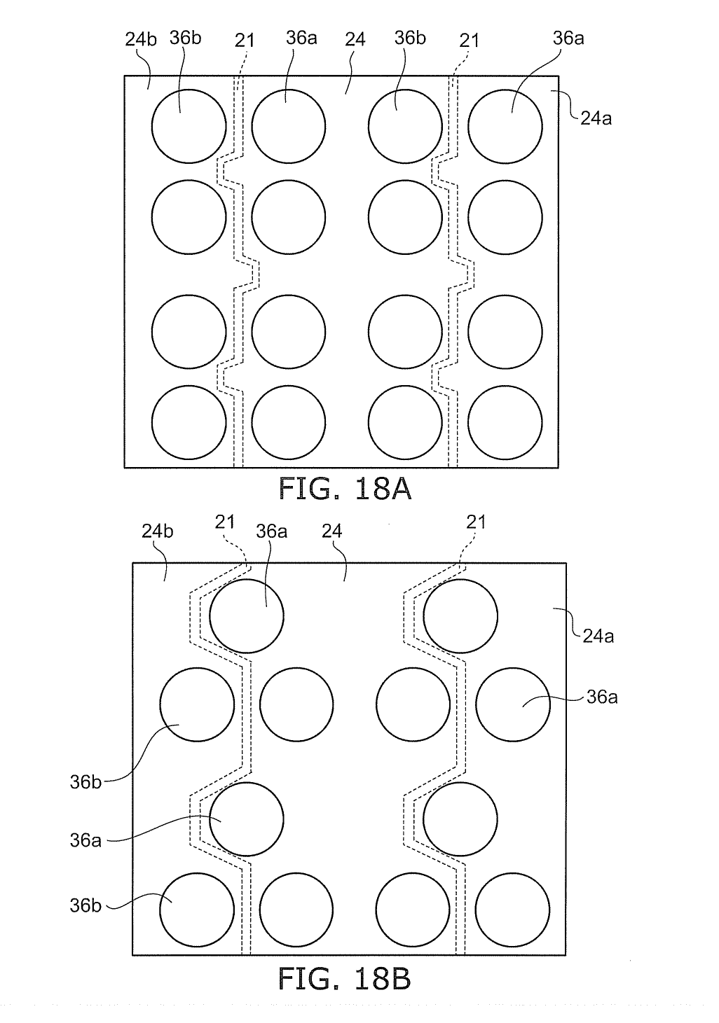

FIGS. 16A to 17B are cross-sectional views of processes, illustrating a method for manufacturing a variation of the third embodiment. FIG. 16B is a bottom view of FIG. 16A.

In this variation, the substrate 10 is separated for each of the light emitting elements. Thus, the individual light emitting elements are protected by the rigid substrate 10. Therefore, a structure having exceedingly high reliability can be provided.

For example, as illustrated in FIG. 16A, a trench 10c is made in the substrate 10 from the light emitting element formation face 10a side in the gap between the light emitting elements. The making of the trench 10c may be performed, for example, prior or subsequent to the light emitting element formation process by a method such as etching, laser dicing, blade dicing, etc.

Thus, when subsequently thinning the substrate 10 by polishing as illustrated in FIG. 16E, the rigid substrate 10 can be subdivided and singulated. Therefore, the risk of undesirable breakage can be reduced. Also, as illustrated in FIG. 17B, a portion where the rigid substrate 10 does not exist is cut during the singulation. Therefore, it is possible to realize high productivity and high yields.

After singulation as well, the substrate 10 and the semiconductor layer 12 do not easily break because the substrate 10 and the semiconductor layer 12 are separated into a small size. Also, the package is flexible as an entirety; and the reliability of the connection points after mounting increases. The warp of the package also is small; and the mounting is easy. It is also possible to mount onto an object having a curved configuration.

Although the trench 21 of the example illustrated in FIG. 15B has a straight-line configuration, it is easy to maintain the mechanical strength even in the case where the substrate 10 is thinned by polishing by using a meandering trench 21 as illustrated in FIGS. 18A and 18B.

Although the metal pillars 26a and 26b and the external terminals 36a and 36b are disposed at positions in substantially a lattice configuration in FIG. 18A, a disposition such as that of FIG. 18B also may be used. Of course, embodiments that separate the substrate 10 may provide similar effects.

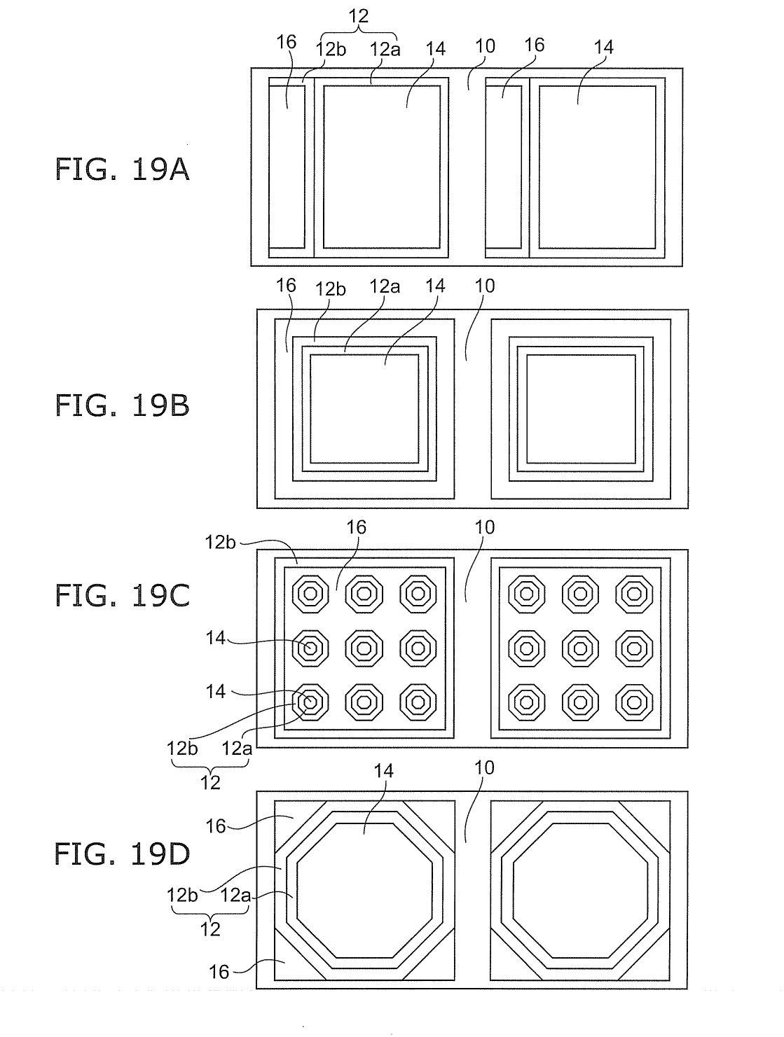

FIGS. 19A to 19D are schematic plan views illustrating variations of the electrode pattern of the light emitting element. Each of FIGS. 19A to 19D illustrates a pattern of two chips.

Because the region where current flows in the vertical direction of the chip emits light, a high light output can be obtained by increasing the surface area of the second semiconductor layer 12a which includes the light emitting layer 12e. In such a case, the surface area where the first semiconductor layer 12b is exposed by removing the second semiconductor layer 12a is an n-type non-light emitting region; and it is easy to provide low contact resistance with the n-side electrode 16 even with a small surface area.

Although it is difficult for the surface area of the n-side electrode 16 to be equal to or less than the size of the bump in the case where flip-chip mounting is performed, in this embodiment, connection to a draw out electrode having a large surface area is possible using the metal interconnect layers 24a and 24b even in the case where the surface area of the n-side electrode 16 is small. By making the surface area of the draw out electrode connected to the p-side electrode 14 substantially the same size as the draw out electrode connected to the n-side electrode 16, mounting on the mounting substrate is possible with good balance via the external terminals 36a and 36b.

In FIG. 19B, the second semiconductor layer 12a, which includes the light emitting layer 12e, is disposed in a central portion; and the n-type first semiconductor layer 12b is disposed to enclose the second semiconductor layer 12a. Thus, the current supply path can be short; and it is easy to align the light emitting region with the optical axis of the lens because the light emitting region is in the central portion.

In FIG. 19C, the semiconductor layers 12 are disposed in positions having a lattice configuration. The n-side electrode 16 is formed around the semiconductor layers 12. The p-side electrodes 14 are provided in the centers of the second semiconductor layers 12a. Thus, the current path can be shorter.

In FIG. 19D, the p-side electrode 14 is disposed in the central portion; and the n-side electrodes 16 are disposed at four corners to enclose the p-side electrode 14. Thus, the light emitting region can be increased; and it is easy to align the light emitting region with the optical axis of the lens because the light emitting region is in the central portion.

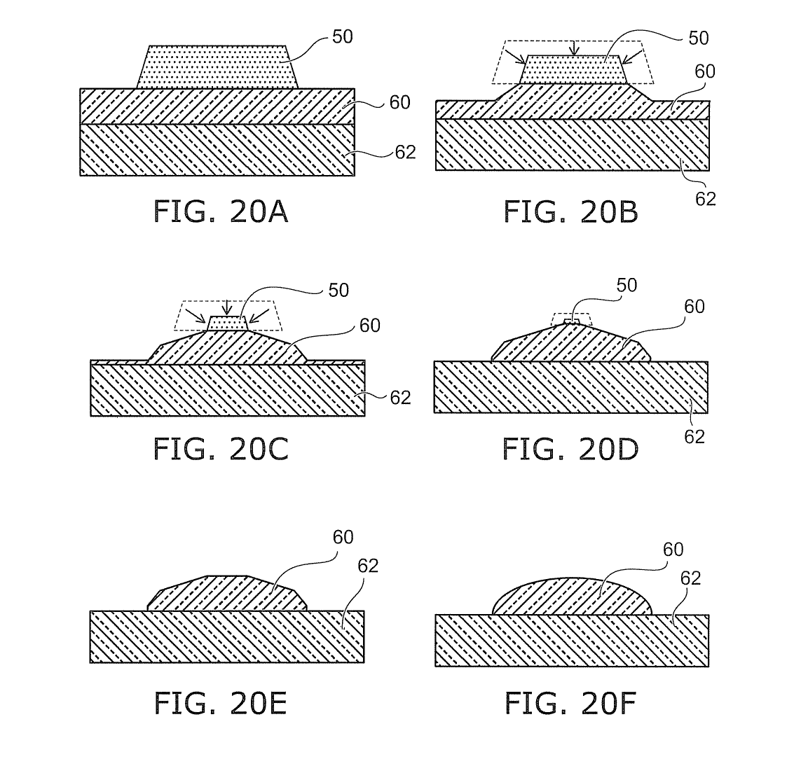

FIGS. 20A to 20F are cross-sectional views of processes, illustrating one example of a lens formation method.

A dot pattern made of a photoresist 50 is formed on quartz glass 60 which is formed on a support body 62, which includes the semiconductor layer 12, the fluorescent layer 30, etc. (FIG. 20A). Processing that has a low selectivity with respect to the resist is performed stepwise in a first step (FIG. 20B), a second step (FIG. 20C), and a third step (FIG. 20D). In each of the steps, the resist dot pattern is reduced by the etching; and the portions surrounding the photoresist 50 become inclined.

Therefore, after peeling the resist, the incline of the cross section becomes steeper downward (FIG. 20E). Then, by performing specular surface processing using isotropic etching with Chemical Dry Etching (CDE) or wet etching to smooth the surface, the lens 60 is completed (FIG. 20F). Thus, it is possible to form a convex lens or a concave lens.

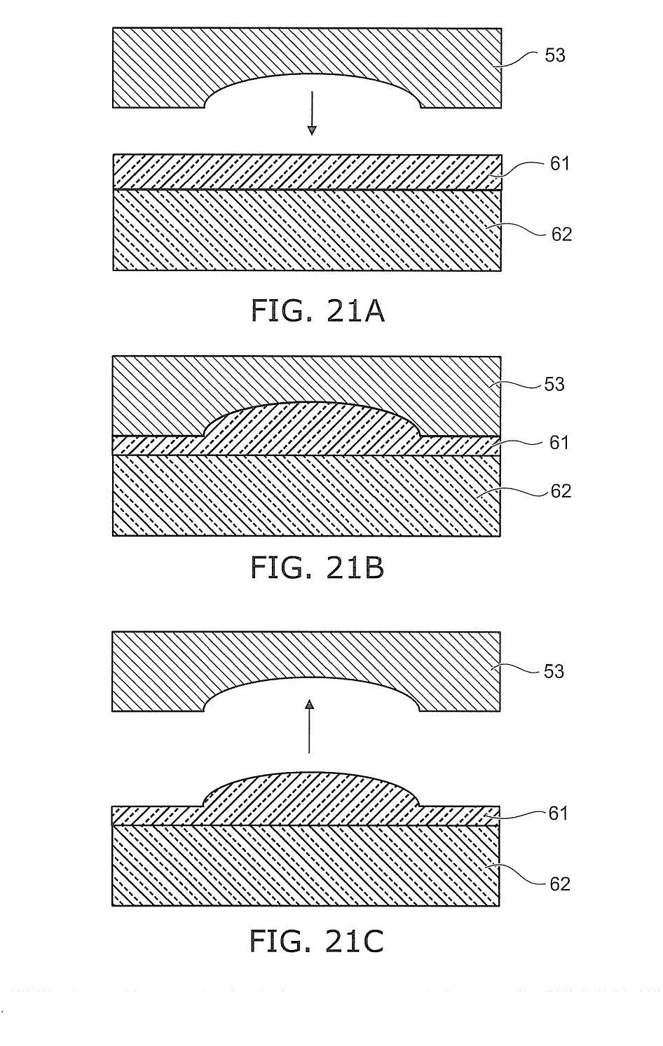

FIGS. 21A to 21C are cross-sectional views of processes, illustrating another example of a lens formation method.

This example uses imprinting. A Spin On Glass (SOG) 61 and the like, which has a liquid form with the characteristic of becoming a glass when heated, is coated onto the support body 62 by performing spin coating (FIG. 21A). After forming the lens configuration by pressing a stamper 53 which is formed into the configuration of the lens (FIG. 21B), the stamper 53 is lifted; and the SOG 61 is glassed by heating (FIG. 21C). By such a method, it is possible to design a stamper 53 with any shape. Therefore, a lens having any configuration can be manufactured easily.

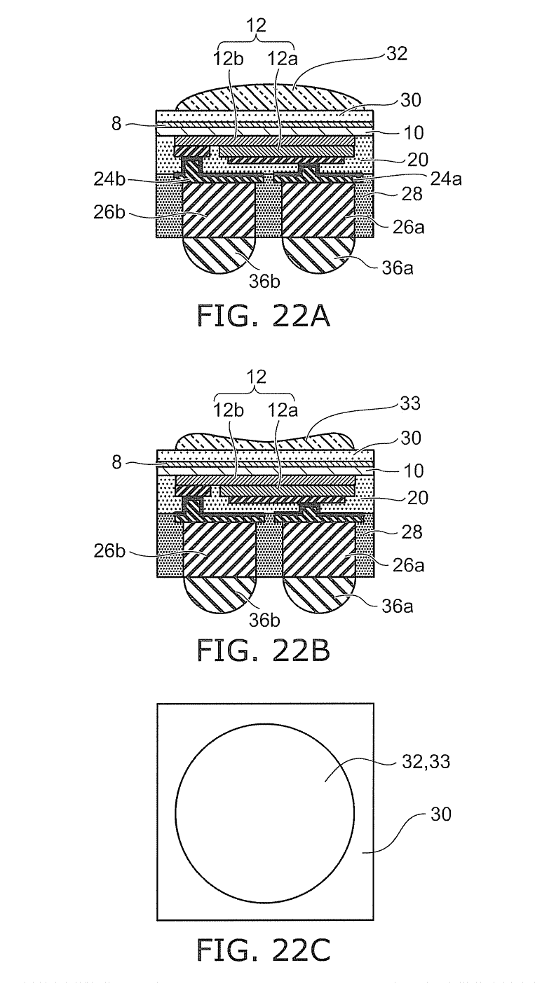

FIGS. 22A to 22C are schematic views of a semiconductor light emitting device having a lens of a variation. FIG. 22A is a cross-sectional view in which the convex lens 32 is a single lens. FIG. 22B is a cross-sectional view in which the concave lens 33 is a single lens. FIG. 22C is a top view.

The lens is not limited to an array lens. A single lens may be used as illustrated in FIGS. 22A to 22C. The optical design and the manufacturing processes can be simplified by using a single lens.

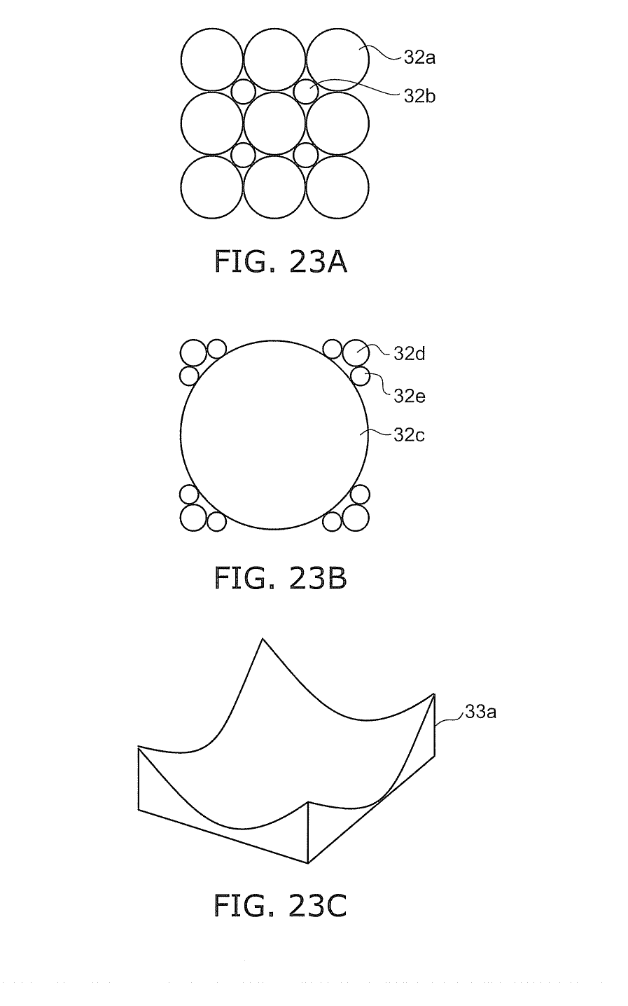

FIGS. 23A to 23C are schematic views of the light emitting device having lenses of other variations.

As illustrated in the schematic plan views of FIGS. 23A and 23B, lenses 32a, 32b, 32c, 32d, and 32e, which have different sizes, may be arranged. By disposing small lenses in the gaps between large lenses, it is possible to increase the region covered with the lenses. As illustrated in the schematic perspective view of FIG. 23C, a lens 33a having a square profile also may be used.

In the embodiments and the variations described above, semiconductor light emitting devices downsized to approach the bare chip size are provided. It is possible to use such semiconductor light emitting devices widely in illumination devices, backlight light sources of image display devices, display devices, etc.

High productivity is easy by the manufacturing method thereof because it is possible to perform the assembly processes and the inspection processes at the wafer level. Therefore, cost reductions are possible.

### First Comparative Example

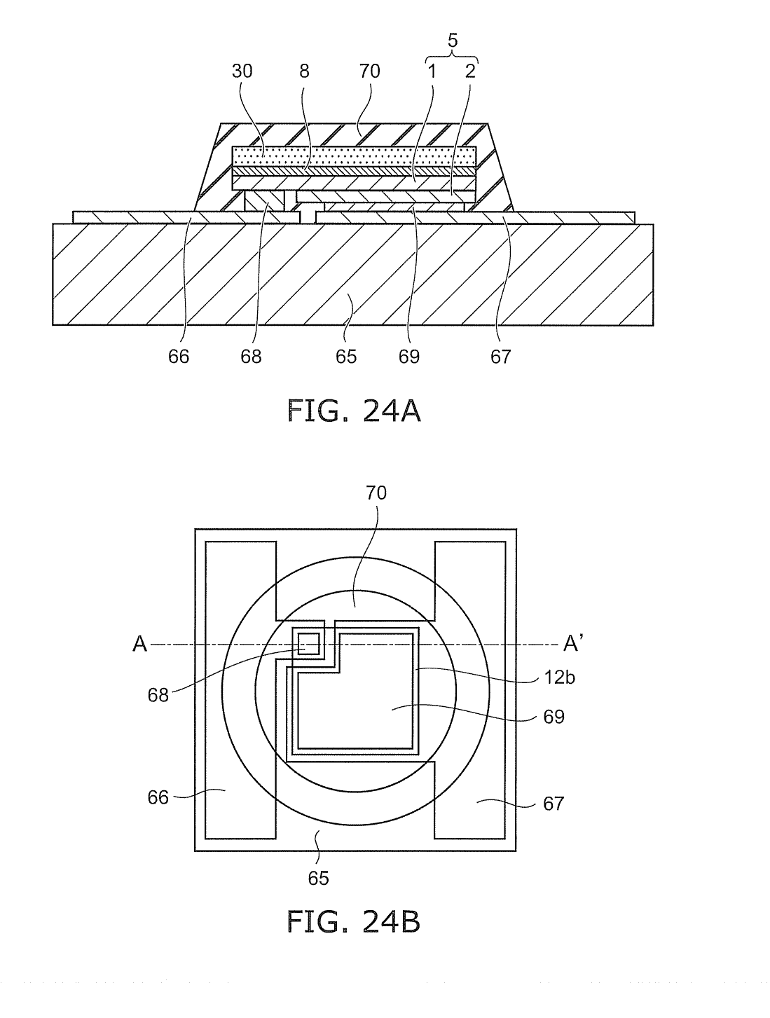

FIG. 24A is a cross-sectional view illustrating a semiconductor light emitting device of a first comparative example. FIG. 24B is a top view of the semiconductor light emitting device illustrated in FIG. 24A. FIG. 24A corresponds to the cross section along line A-A′ of FIG. 24B.

In FIG. 24A, a semiconductor junction portion (a pn junction) between an n-type semiconductor 1 and a p-type semiconductor 2 forms a light emitting portion; and basically, a light emitting diode (LED) chip (hereinbelow, referred to as an LED chip 5) is formed between the n-type semiconductor 1 and the p-type semiconductor 2.

Although the detailed configuration of the LED chip 5 is omitted herein, normally, a semiconductor (e.g., GaN) having a relatively large bandgap is used as the n-type semiconductor 1 and the p-type semiconductor 2; and a semiconductor (e.g., InGaN) having relatively small bandgap is inserted between the n-type semiconductor 1 and the p-type semiconductor 2 as an active layer. Thereby, injected carriers (minority carriers) are effectively confined in the active layer by the pn junction; effective light emission occurs due to recombination of the minority carriers; and a high luminous efficacy is obtained. Hereinbelow, only the representative n-type semiconductor 1 and p-type semiconductor 2 of the LED chip 5 are described. Although an example is recited above in which a light emitting diode (LED) is used, a semiconductor laser (a Laser Diode (LD)) also may be used.

In FIG. 24A, an n-side interconnect electrode 66 and a p-side interconnect electrode 67 are formed on a package substrate 65. The n-type semiconductor 1 is connected to the n-side interconnect electrode 66 via an n-side bonding metal 68. The p-type semiconductor 2 is connected to the p-side interconnect electrode 67 via a p-side bonding metal 69.

The fluorescent reflecting film 8, which has a low reflection with respect to the light emission wavelength of the light emitting element and a high reflection with respect to the light emission wavelength of the phosphor, is provided on the LED chip 5. The fluorescent layer 30, which is excited by the light of the light emitting element to emit light having a wavelength different from that of the light emitting element, is provided thereupon. The fluorescent layer 30 is protected by a protective film 70.

Here, it is desirable for the package substrate 65 to include a material having a high thermal conductivity (Cu, Al, Si, SiC, AlN, Al₂O₃, etc.) to effectively dissipate heat emitted by the LED chip 5. Although it is desirable for the package substrate 65 to be insulative because of the existence of the interconnect electrodes 66 and 67, in the case where the substrate is conductive, at least one selected from the interconnect electrodes 66 and 67 may be insulated from the substrate by providing a thin insulating film between the substrate and the interconnect electrodes 66 and 67.

The interconnect electrodes 66 and 67 are, for example, Cu films having a thickness of 12 μm with Ni plating of 5 μm and Au plating of 0.2 μm provided on the surface. The bonding metals 68 and 69 may be made of a conductive material such as solder, Ag paste, Au bumps, etc., and may be selected based on the mounting method of the LED chip 5 such as thermal melting, thermal curing, ultrasonic connection, etc.

Similarly to the embodiments described above, the fluorescent reflecting film 8 has the functions of effectively irradiating the light (having the wavelength λ₀) emitted by the LED chip 5 onto the fluorescent layer 30 and reflecting the light emitted by the fluorescent layer 30. In other words, the configuration is such that although the light of the wavelength λ₀ is transmitted easily, light of other wavelengths is relatively reflected. As a result, although the excitation light (λ₀) of the LED chip 5 passes through the fluorescent reflecting film 8 to be irradiated onto the fluorescent layer 30, the component of the light emitted by the phosphor toward the LED chip 5 side is reflected by the fluorescent reflecting film 8 and output externally. In other words, the proportion of the desired light emitted by the phosphor lost due to internal scattering and internal absorption is reduced; and the luminous efficacy as viewed from the outside can be increased.

The phosphor included in the fluorescent layer 30 may include, for example, YAG (Ce) for yellow; Y₂O₂S:Eu, YVO₄:Eu, etc., for red; ZnS:Cu,Al, (Ba, Mg)Al₁₀O₁₇:Eu,Mn, etc., for green; and (Ba, Mn)Al₁₀O₁₇:Eu, (Sr, Ca, Ba, Mg)₁₀(PO₄)₆Cl₂: Eu, etc., for blue.

A phosphor may have a paste form in which a fine powder dispersed in a matrix resin is screen printed and cured by a method such as heat treatment or UV curing, or may be formed by adhering a resin sheet by thermal compression bonding. The matrix resin may include various resins such as acrylic, polyester, silicone, epoxy, polyimide, etc.

The protective film 70 may include a resin transparent to the light emitted by the phosphor such as, for example, acrylic resin, silicone resin, epoxy resin, etc. The protective film 70 also may include an inorganic film other than a resin such as an oxide film or a nitride film.

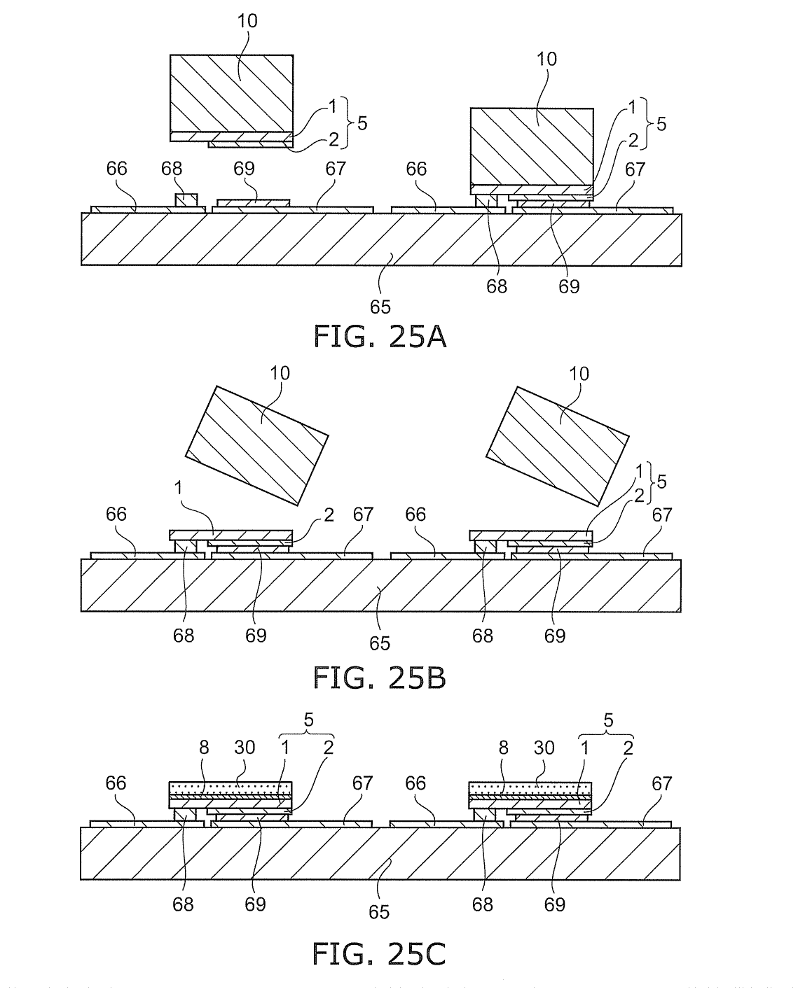

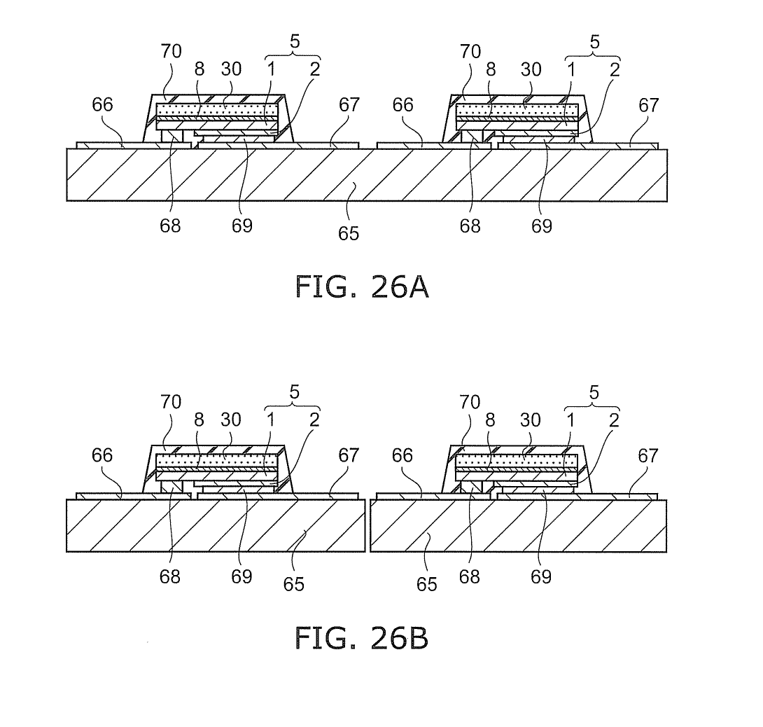

FIG. 25A to FIG. 26B are schematic cross-sectional configuration diagrams illustrating an example of manufacturing processes of the semiconductor light emitting device of the first reference example.

FIG. 25A illustrates the state in which the LED chip 5 undergoes flip chip connection after the interconnect electrodes 66 and 67 and the bonding metals 68 and 69 are formed on a mounting substrate 65 by photolithography and the like in the wafer state. Because the formation processes proceed in the wafer state, it is easy to perform collective patterning such as photolithography and screen printing.

The flip chip connection of the LED chip 5 may be performed by using a method that, for example, forms a Au electrode on the mounting substrate 65 side and forms a Sn electrode on the LED chip 5 side beforehand; positionally aligns the mounting substrate 65 and the LED chip 5; and forms eutectic AuSn by thermal melting. AuSn eutectic solder may be plated beforehand; and other solder materials may be used. Also, a metal powder resin mixture such as Ag paste may be used.

FIG. 25B illustrates the process in which the substrate 10 of the LED chip 5 is removed. In this example, the LED chip 5 is flip-chip mounted. Therefore, the light is extracted from the substrate 10 side of the LED chip 5; and the extraction is to reduce the amount of light absorbed by the LED substrate 10 and to reduce the thickness of the LED chip 5 to the minimum necessary thickness because of the sealing process described below.

The removal method of the substrate 10 of the LED chip 5 may include polishing, etching, lift-off using a spacer, etc., of the substrate 10. For example, such methods may be used for InGaN/GaN materials with a sapphire substrate. Lift-off using a spacer is effective in the case where a GaN substrate is used with the materials recited above. Generally, by removing the substrate 10, the thickness of the LED chip 5 becomes about 5 to 10 μm.

FIG. 25C is a process forming the fluorescent reflecting film 8 described above after the process of removing the substrate 10 recited above. The fluorescent reflecting film 8 formed in portions other than the LED chip 5 may be removed by photolithography. The fluorescent reflecting film 8 is formed by depositing, for example, a SiO₂ film or a Si₃N₄ film using plasma Chemical Vapor Deposition (CVD) at 250° C. At this time, because the LED chip 5 is connected with AuSn solder, the solder can be prevented from melting and shifting.

Alternatively, the fluorescent reflecting film 8 may have a multilayered structure of the dielectric films as described above referring to FIGS. 6A and 6B.

After forming the fluorescent reflecting film 8, the fluorescent layer 30 is formed. The fluorescent layer 30 may be formed by screen printing a phosphor paste, in which a phosphor is dispersed in a resin matrix, and then curing by heat treatment. An ultraviolet-curing resin may be used as the resin matrix; and Ultra-Violet (UV) curing may be used. At this time, the phosphor may include, for example, a mixture of the three colors of RGB; or separate pastes may be overlaid.

FIG. 26A illustrates the formation of the protective film 70. The protective film 70 is formed to cover the fluorescent layer 30. The protective film 70 may be formed by screen printing similar to that of the fluorescent layer 30 in the case where the protective film 70 is formed of a resin. Or, a photosensitive resin may be formed by photolithography. Further, the protective film 70 may include an oxide film, a nitride film, a combined film of a resin and an oxide film, and a combined film of a resin and a nitride film.

FIG. 26B illustrates the separation of the semiconductor light emitting devices after completing the wafer processing processes. It is sufficient to perform the separation using dicing which is a general semiconductor processing method.

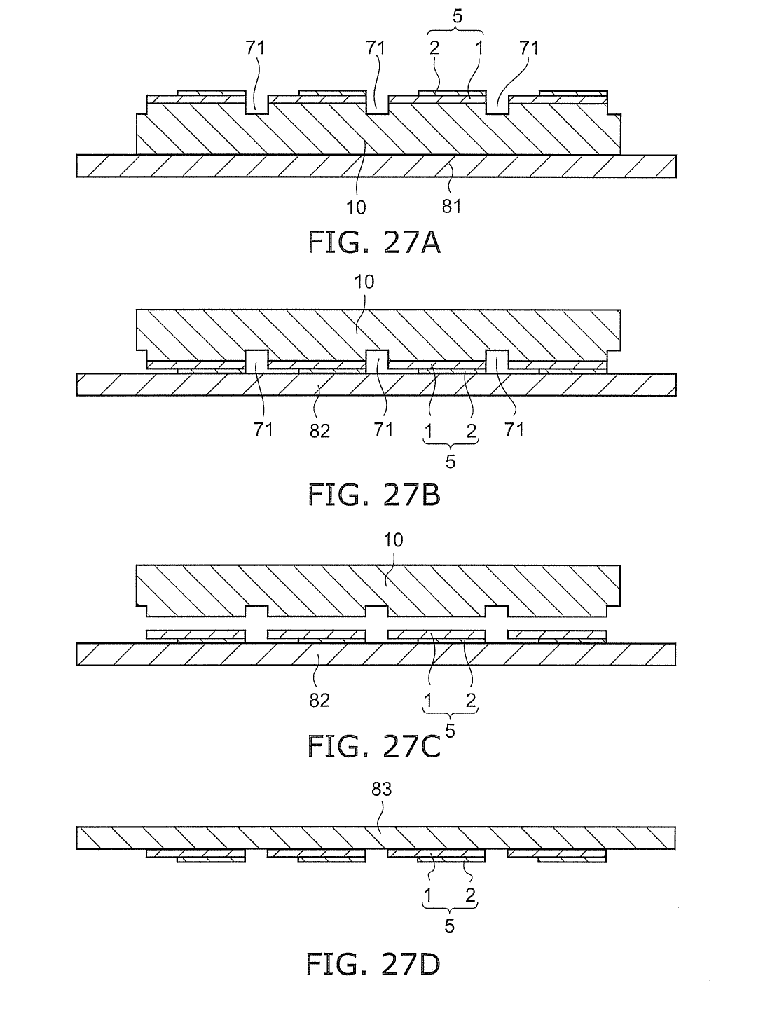

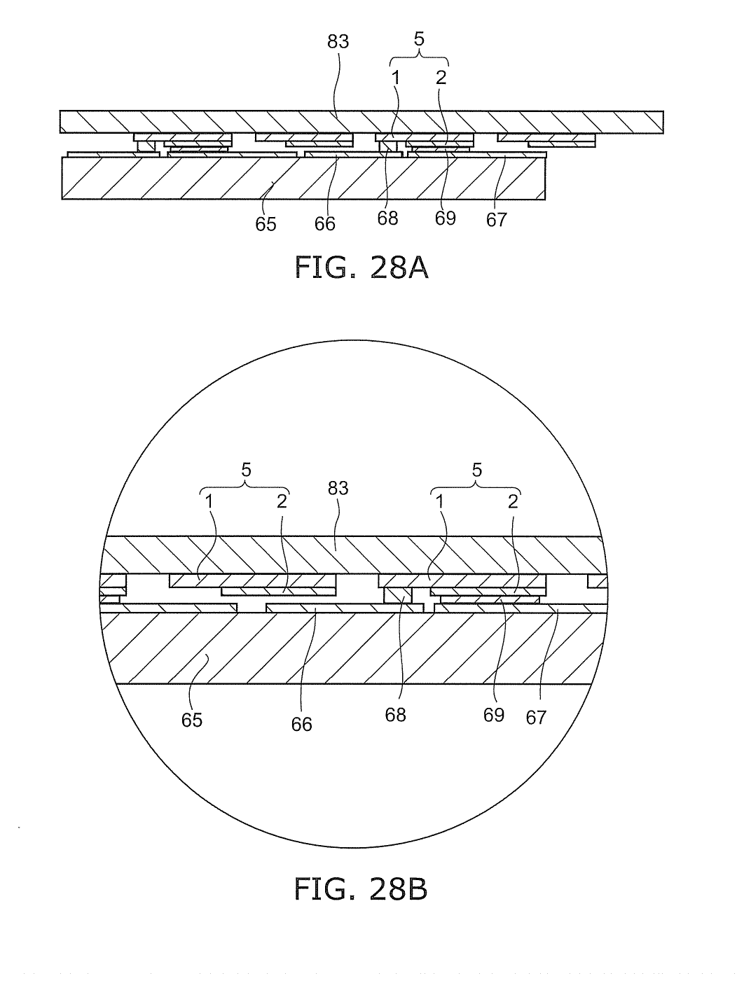

FIG. 27A to FIG. 28B illustrate an example in which the processes described above are improved. Instead of performing the peeling of the substrate 10 of the LED chip 5 from the mounting substrate 65, the peeling is performed beforehand in the arrangement of the wafer state.

First, the LED wafer is adhered to a dicing tape 81; and a dicing trench 71 is made in the LED separation portion from the surface to a position deeper than the n-type semiconductor 1. At this stage, the trench is made (half-cut) partway through the substrate 10. Instead of making a half-cut by dicing, trench etching to the substrate 10 may be performed by photolithography and etching.

Then, the LED wafer is adhered to a transfer tape 82 such that the LED substrate 10 is exposed upward (FIG. 27B). Continuing, the substrate 10 is removed collectively using etching, lift-off using a spacer, substrate polishing, etc. (FIG. 27C). Then, plasma CVD of a SiO₂ film or a Si₃N₄ film is performed to form the fluorescent reflecting film 8 described above. In such a case, it is desirable to use a polyimide tape as the transfer tape 82 described above to withstand the heat of the plasma CVD. Subsequently, the fluorescent layer 30 is formed. The fluorescent reflecting film 8 and the fluorescent layer 30 may be formed after mounting the LED chip 5 on the mounting substrate 65 as described above and are not illustrated herein.

Continuing, the LED chip 5 is transferred onto another tape 83 to expose the surface of the LED chip 5 (FIG. 27D). At this time, it is desirable to use a thermal peeling tape or a UV peeling tape as the transfer tape 83.

Finally, the LED chip 5 is flip-chip mounted onto the mounting substrate wafer 65 (FIG. 28A). At this time, the flip-chip mounting can be performed efficiently by setting the arrangement pitch of the LED chip mounting portions of the mounting substrates 65 to the arrangement pitch of the LED chips 5 multiplied by a whole number.

For example, by setting the LED mounting portion pitch of the mounting substrate 65 to twice the LED chip arrangement pitch, it is possible to perform a collective mounting of every other LED chip 5; and as described below, one LED wafer can be used to collectively transfer the LED chips onto four mounting substrate wafers.

Methods for transferring the LED chip 5 onto the mounting substrate 65 may include using an adhesive material such as silver paste as the bonding metals 68 and 69; positionally aligning the LED chip 5 with the interconnect electrodes 66 and 67; and pressing the transfer tape 83 onto the mounting substrate 65.

At this time, as illustrated in FIG. 28B, the LED chips 5 positioned at the LED mounting portions (the portions of the bonding metals 68 and 69) of the mounting substrates 65 are peeled by the adhesive force of the silver paste; while the other LED chips 5 remain adhered as-is to the transfer tape 83.

For more reliable contact between the silver paste and the LED chips 5, a pressing plate having pins or protrusions may be pressed onto the LED chips 5 positioned at the LED mounting portions of the mounting substrates 65 in the state illustrated in FIG. 28B from the backside of the transfer tape 83. Or, for more reliable peeling of the LED chips 5 to be transferred, a UV peeling tape or a thermal peeling tape may be used as the transfer tape 83 and UV irradiation may be performed selectively on the transfer tape 83 of the LED mounting portions; or a pressing plate having pins or protrusions may be used to apply heat.

Instead of using the adhesive materials as described above, for example, the LED chips 5 at the portions of the bonding metals 68 and 69 may be selectively bonded by solder by using a solder material as the bonding metals 68 and 69 and by melting the solder by heating the mounting substrate 65 in the state illustrated in FIG. 28B. Or, a thermal peeling tape may be used as the transfer tape 83; peeling of the LED chips 5 may be performed selectively by heating the mounting substrates 65 in the state illustrated in FIG. 28B such that the solder does not melt; and subsequently, performing reflow collectively by placing the entirety of the mounting substrates 65 into a reflow oven.

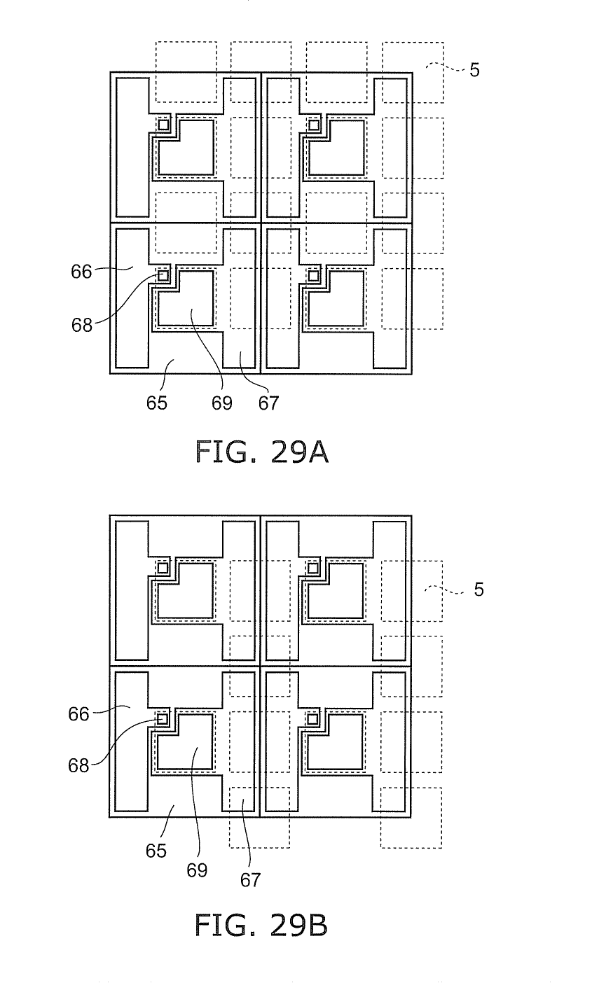

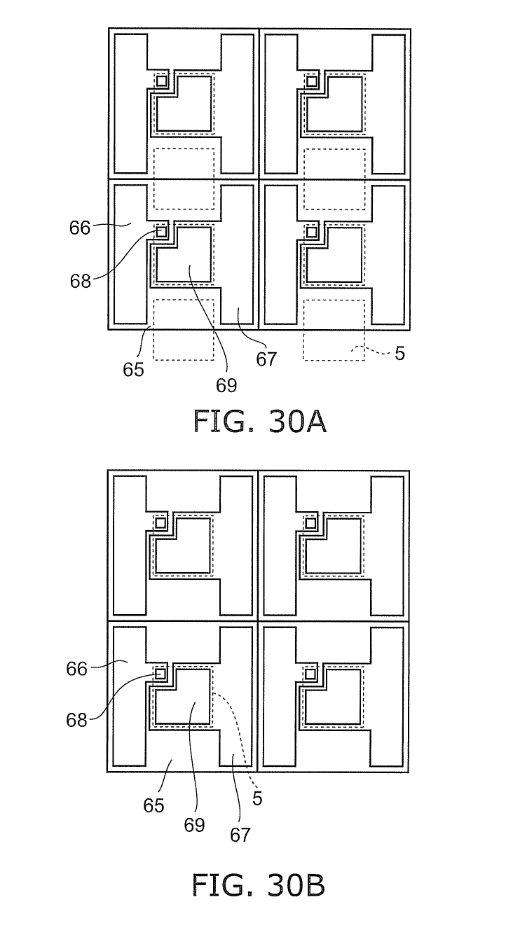

FIG. 29A to FIG. 30B are top views illustrating a process of transferring in the case where the arrangement pitch of the mounting substrates 65 is twice the arrangement pitch of the LED chips 5.

FIG. 29A illustrates the transfer process of the first mounting substrate 65. The conditions are illustrated in which only one of four adjacent LED chips 5 is transferred.

Then, the LED chips 5 are transferred in turn onto the other mounting substrates 65. FIG. 29B illustrates the LED chip transfer process onto the second mounting substrate 65. FIG. 30A illustrates the LED chip transfer process onto the third mounting substrate 65. FIG. 30B illustrates the LED chip transfer process onto the fourth mounting substrate 65.

Thus, by setting the arrangement pitch of the mounting substrates 65 to twice the arrangement pitch of the LED chips 5, the LED chips 5 can be collectively transferred from one LED wafer onto four wafers of the mounting substrates 65.

### Second Comparative Example

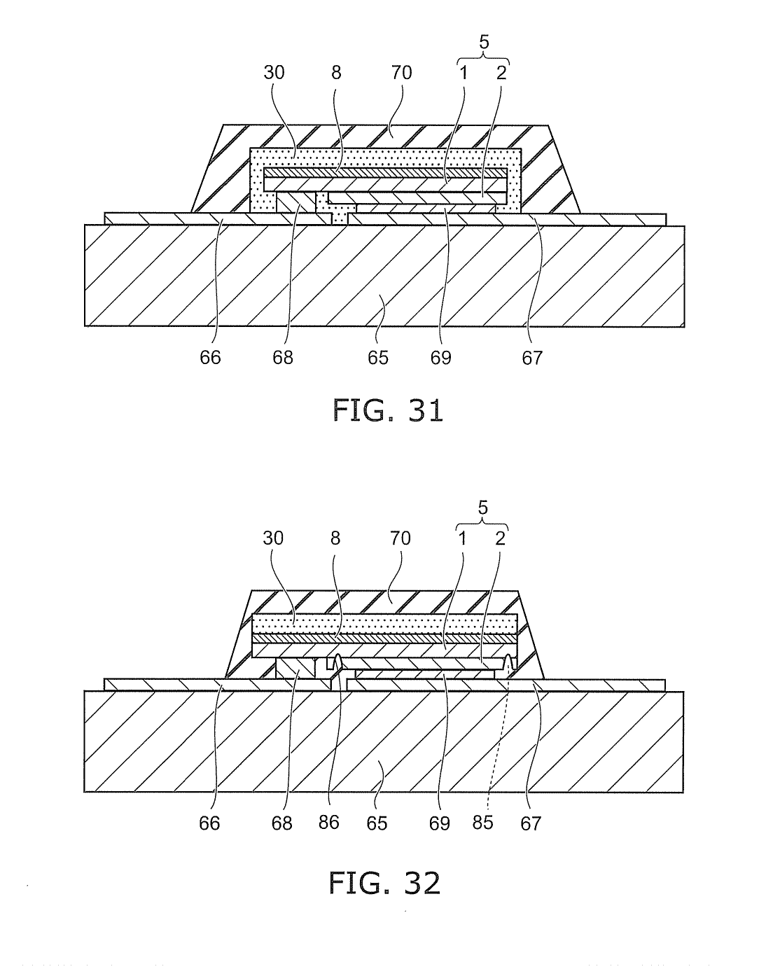

FIG. 31 is a cross-sectional configuration diagram illustrating the semiconductor light emitting device of a second comparative example. Portions similar to those of FIG. 24A are marked with like numerals.

A feature of this example is that the fluorescent layer 30 is formed not only on the upper face of the light emitting element (the LED chip 5) but also on the side faces; and uneven colors related to the light amount balance between the light emitted by the phosphor and the light emitted from the side faces of the light emitting element can be reduced. When performing the coating of a resin having the phosphor dispersed therein, this example can be realized by performing the coating not only on the upper face of the light emitting element but also to cover a region around the light emitting element larger than the light emitting element by an amount equal to about the thickness of the light emitting element. It is desirable for the coating of the fluorescent layer 30 to be performed in a reduced-pressure atmosphere to prevent the mixing of bubbles.

### Third Comparative Example

FIG. 32 illustrates a third comparative example which provides effects similar to those of the second comparative example illustrated in FIG. 31. In this example, uneven colors do not easily occur even though the fluorescent layer 30 is formed only on the upper face of the fluorescent reflecting film 8.

In this example, a trench 85, which vertically pierces the light emitting layer (the pn junction portion) of the light emitting element, is made in a circumferential edge portion of the light emitting element; and a metal (a light shielding film) 86, which is a metal of the electrodes of the element or a metal other than that of the electrodes, is provided on the surface of the trench 85 via an insulating film (not illustrated).

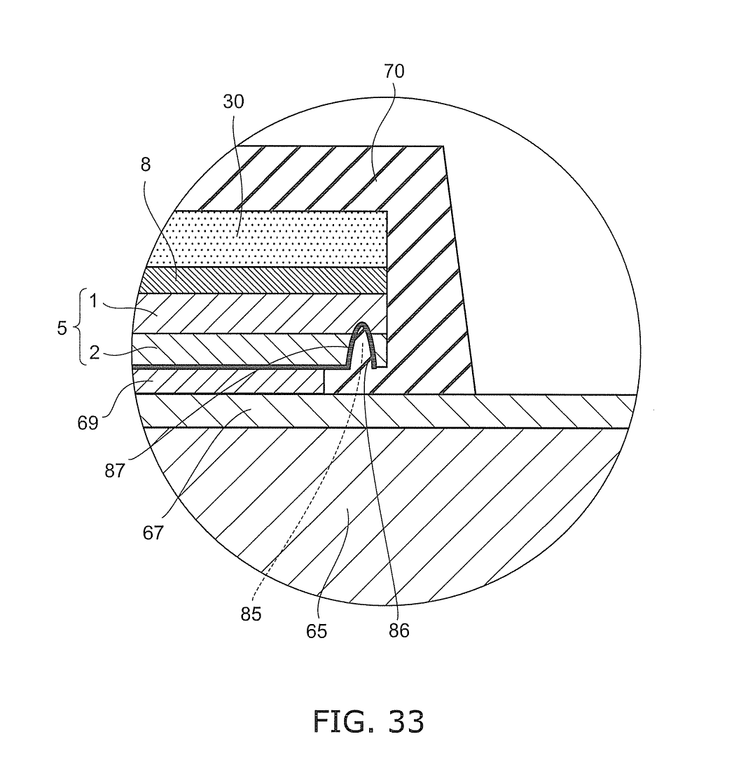

This portion is enlarged in FIG. 33. Here, the example is illustrated in which the electrode metal of the p-type semiconductor 2 is extended into the trench 85 to form the light shielding film 86. In such a case, a thin insulating film 87 (e.g., a silicon oxide film or a silicon nitride film of 100 nm) is provided on the surface of the trench 85; and leak current flowing outside the pn junction of the light emitting element is prevented.

As described above, instead of using the electrode metal as the light shielding film 86, the light shielding film 86 may be formed of a dedicated metal other than the electrode metal. Also, instead of metal, a black body resin including a light-absorbing material such as carbon may be provided. Thereby, the light guided by the active layer portions of the light emitting element and extracted in the side face directions can be blocked to suppress uneven colors; and in the case of a metal light shielding film 86, such light can be reflected in the upward direction of the drawings to increase the luminous efficacy.

The invention is not limited to the embodiments described above. For example, although the embodiments described above are illustrated by several specific examples, these are merely configuration examples; and other means (materials, configurations, dimensions, etc.) may be used in each of the components according to the purport of the invention. Further, it is also possible to practice the embodiments in combination. In other words, the invention is practicable with various variations without departing from the purport of the invention.

A red fluorescent layer may contain, for example, a nitride-based phosphor of CaAlSiN₃:Eu or a SiAlON-based phosphor.

In the case where a SiAlON-based phosphor is used, it may be used

(M₁₋ₓRₓ)ₐ₁AlSi_{b1}O_{c1}N_{d1} Compositional Formula (1)

where M is at least one type of metal element excluding Si and Al, and it may be desirable for M to be at least one selected from Ca and Sr; R is a light emission center element, and it may be desirable for R to be Eu; and x, a1, b1, c1, and d1 satisfy the relationships 0<x≦1, 0.6<a1<0.95, 2<b1<3.9, 0.25<c1<0.45, and 4<d1<5.7.

By using the SiAlON-based phosphor of Compositional Formula (1), the temperature characteristics of the wavelength conversion efficiency can be improved; and the efficiency in the high current density region can be improved further.

A yellow fluorescent layer may contain, for example, a silicate-based phosphor of (Sr, Ca, Ba)₂SiO₄:Eu.

A green fluorescent layer may contain, for example, a halophosphate-based phosphor of (Ba, Ca, Mg)₁₀(PO₄)₆.Cl₂:Eu or a SiAlON-based phosphor.

In the case where a SiAlON-based phosphor is used, it may be used

(M_{1- x}Rₓ)ₐ₂AlSi_{b2}O_{c2}N_{d2} Compositional Formula (2)

where M is at least one type of metal element excluding Si and Al, and it may be desirable for M to be at least one selected from Ca and Sr; R is a light emission center element, and it may be desirable for R to be Eu; and x, a2, b2, c2, and d2satisfy the relationships 0<x≦1, 0.93<a2<1.3, 4.0<b2 <5.8, 0.6<c2<1, and 6<d2<11.

By using the SiAlON-based phosphor of Compositional Formula (2), the temperature characteristics of the wavelength conversion efficiency can be improved; and the efficiency in the high current density region can be improved further.

A blue fluorescent layer may contain, for example, an oxide-based phosphor of BaMgAl₁₀O₁₇:Eu.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

What is claimed is:

1-30. (canceled)

31. A semiconductor light emitting device, comprising:
a semiconductor layer including a first face, a second face opposite to the first face, and a light emitting layer;
a p-side electrode provided on the second face of the semiconductor layer;
an n-side electrode provided on the second face of the semiconductor layer;
an insulating film provided on the second face side of the semiconductor layer, the insulating film having a first opening reaching the p-side electrode and a second opening reaching the n-side electrode;
a p-side interconnect electrode including a p-side metal interconnect layer and a p-side metal pillar, the p-side metal interconnect layer being provided in the first opening and on the insulating film, the p-side metal pillar being provided on the p-side metal interconnect layer;
an n-side interconnect electrode including an n-side metal interconnect layer and an n-side metal pillar, the n-side metal interconnect layer being provided in the second opening and on the insulating film, the n-side metal pillar being provided on the n-side metal interconnect layer, a contact surface area between the n-side metal interconnect layer and the n-side metal pillar being greater than a contact surface area between the n-side metal interconnect layer and the n-side electrode;
a resin provided between the p-side metal pillar and the n-side metal pillar;
a fluorescent layer provided on the first face side of the semiconductor layer; and
a fluorescent reflecting film provided on the first face side and a side surface of the semiconductor layer.

32. The device of claim 31, wherein a substrate is not provided between the first face and the fluorescent layer.

33. The device of claim 31, wherein the fluorescent layer is provided on an outer side of a side surface of the fluorescent reflection film.

34. The device of claim 31, wherein a reflectance of the fluorescent reflecting film with respect to a fluorescent wavelength of the fluorescent layer is higher than a reflectance of the fluorescent reflecting film with respect to a light emission wavelength of the light emitting layer.

35. The device of claim 31, wherein a structure of the fluorescent reflecting film includes a first dielectric film repeatedly stacked alternately with a second dielectric film, the first dielectric film and the second dielectric film having mutually different refractive indexes.

36. The device of claim 31, wherein the second face of the semiconductor layer has a difference in levels, the n-side electrode being provided on a lower level portion, the p-side electrode being provided on an upper level portion.

37. The device of claim 36, wherein a surface area of the upper level portion is greater than a surface area of the lower level portion.

38. The device of claim 31, wherein a planar size of the p-side electrode is greater than a planar size of the n-side electrode.

39. The device of claim 31, wherein each of a thickness of the p-side metal pillar and a thickness of the n-side metal pillar is thicker than a thickness of a stacked body including the semiconductor layer, the p-side electrode, the n-side electrode, the insulating film, the p-side metal interconnect layer, and the n-side metal interconnect layer.

40. The device of claim 31, wherein a contact surface area between the p-side metal interconnect layer and the p-side metal pillar is greater than a contact surface area between the p-side metal interconnect layer and the p-side electrode.

41. The device of claim 31, wherein the fluorescent reflecting film is provided in contact with the first face of the semiconductor layer.

42. The device of claim 31, wherein a portion of the n-side metal interconnect layer extends to a position below the light emitting layer.

43. The device of claim 31, wherein a size of the fluorescent layer is substantially same as a size of the fluorescent reflecting film.

44. The device of claim 31, wherein an outer side of the resin is aligned with outer sides of the fluorescent layer and the fluorescent reflecting film.

45. The device of claim 31, further comprising an insulating layer provided above the resin and beneath the fluorescent reflecting film, and surrounding the light emitting layer, wherein an outer side of the insulating layer is aligned with an outer side of the resin.

46. The device of claim 44, further comprising an insulating layer provided above the resin and beneath the fluorescent reflecting film, and surrounding the light emitting layer, wherein an outer side of the insulating layer is aligned with the outer side of the resin.

47. The device of claim 31, wherein an outer side of the insulating film is aligned with an outer side of the resin.

48. The device of claim 31, wherein the insulating film is provided above the resin and beneath the fluorescent reflecting film, and surrounding the semiconductor layer.

49. The device of claim 31, wherein each of a thickness of the p-side metal pillar and a thickness of the n-side metal pillar is thicker than a thickness of the semiconductor layer.

50. The device of claim 31, wherein
the semiconductor layer includes a first semiconductor layer having the first face, and
the first semiconductor layer is an n-type first semiconductor layer.

51. The device of claim 31, wherein the side surface of the semiconductor layer continues from the first face.
